(19) United States
(12) Patent Application Publication
(10) Pub. No.: US 2025/0251545 A1
(43) Pub. Date: Aug. 7, 2025

(54) SEMICONDUCTOR PACKAGE AND METHOD OF FORMING THE SAME

(71) Applicant: Taiwan Semiconductor Manufacturing Co., Ltd., Hsinchu (TW)

(72) Inventors: Chen-Hua Yu, Hsinchu (TW); Tung-Liang Shao, Hsinchu (TW); Yu-Sheng Huang, Hemei Township (TW)

(21) Appl. No.: 18/672,410

(22) Filed: May 23, 2024

Related U.S. Application Data
(60) Provisional application No. 63/560,151, filed on Mar. 1, 2024.
(60) Provisional application No. 63/550,700, filed on Feb. 7, 2024.

(51) Int. Cl. G02B 6/12; G02B 6/13; H01L 23/00

(52) U.S. Cl. CPC G02B 6/12002; G02B 6/13; H01L 24/80; H01L 2224/80895

(57) ABSTRACT

A package includes a first interconnect structure that includes conductive features and first waveguides; package modules attached to the first interconnect structure; and optical bridge modules attached to the first interconnect structure, wherein the optical bridge modules are optically coupled to the first waveguides, wherein the optical bridge modules are electrically connected to the corresponding package modules through the first interconnect structure.

### PRIORITY CLAIM AND CROSS-REFERENCE

This application claims the benefit of U.S. Provisional Application No. 63/550,700, filed on Feb. 7, 2024, and U.S. Provisional Application No. 63/560,151, filed on Mar. 1, 2024, which applications are hereby incorporated herein by reference.

### BACKGROUND

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) components and electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, and 7 illustrate intermediate steps in the formation of an optical bridge module, in accordance with some embodiments.

FIGS. 8, 9, 10, 11, 12, 13, 14, 15, and 16 illustrate cross-sectional views of intermediate steps in the formation of a package module, in accordance with some embodiments.

FIGS. 17, 18, and 19 illustrate cross-sectional views of intermediate steps in the formation of an interposer structure, in accordance with some embodiments.

FIGS. 20, 21, 22, 23, and 24 illustrate cross-sectional views of intermediate steps in the formation of a package, in accordance with some embodiments.

FIGS. 25A and 25B illustrate plan views of packages, in accordance with some embodiments.

FIGS. 26, 27, 28, and 29 illustrate cross-sectional views of intermediate steps in the formation of a package, in accordance with some embodiments.

FIG. 30 illustrates a cross-sectional view of a package, in accordance with some embodiments.

FIG. 31 illustrates a cross-sectional view of a package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various structures such optical bridge modules and packages and their methods of formation are described herein. A package includes package modules and optical bridge modules attached to an interconnect structure or an interposer structure that has waveguides formed within. The waveguides allow for package-level optical communication between the package modules. The waveguides are optically coupled to the optical bridge modules, and the optical bridge modules act as an interface between the package modules and the waveguides. In this manner, both electrical and optical communication is facilitated between multiple modules of a package. In some embodiments, within a package, electrical signals may be used for some short-distance communication and optical signals may be used for some long-distance communication.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

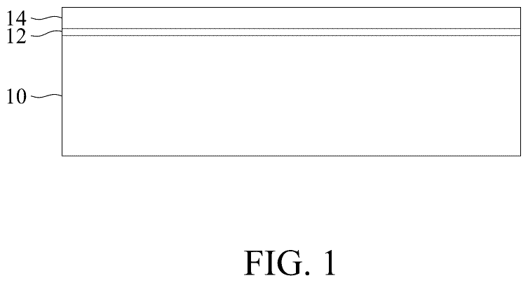

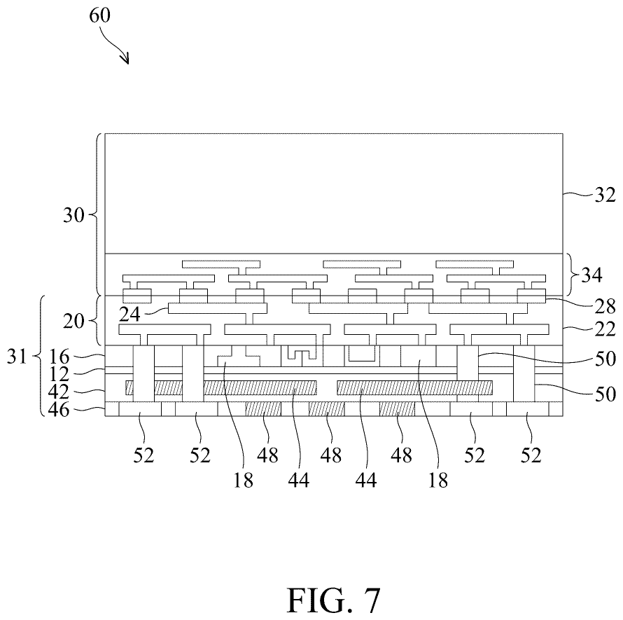

FIGS. 1 through 7 illustrate intermediate steps in the formation of an optical bridge module 60 (see FIG. 7), in accordance with some embodiments. The optical bridge module 60 comprises photonic components and waveguides that may be configured to receive, generate, modify, transmit, and/or process optical signals. In this manner, the optical bridge module 60 may provide an interface for optical communication between modules in a package. In this manner, the optical bridge module 60 can enable optical-electrical (OE) conversion for package-level optical communication (e.g., within a package). In some cases, the optical bridge module 60 may be considered an optical engine module, an optical-electrical (OE) module, an optical package module, or the like.

Turning to FIG. 1, the optical bridge module 60 comprises at this stage a substrate 10, a dielectric layer 12, and photonic layer 14. In an embodiment, at a beginning of the manufacturing process of the optical bridge module 60, the substrate 10, the dielectric layer 12, and the photonic layer 14 may collectively be part of a silicon-on-insulator (SOI) substrate or the like, which may be doped (e.g., with a p-type or an n-type dopant) or undoped. The substrate 10 may be a wafer, such as a silicon wafer. Other substrates, such as a silicon-on-insulator (SOI) substrate, a multi-layered substrate, or a gradient substrate may also be used. In some embodiments, the semiconductor material of the substrate 10 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In other embodiments, the substrate 10 may be a dielectric material such as silicon oxide, glass, ceramic, plastic, or any other suitable material that allows for structural support of overlying devices. In some embodiments, multiple optical bridge modules 60 may be formed on a single substrate 10 and then may be subsequently singulated into individual optical bridge modules 60. The substrate 10 may be free of passive or active devices, in some cases.

The dielectric layer 12 may be a dielectric layer that separates the substrate 10 from the overlying photonic layer 14 and can additionally, in some embodiments, serve as a portion of cladding material that surrounds the subsequently manufactured photonic components 18 (described below). In an embodiment, the dielectric layer 12 may be silicon oxide, silicon nitride, germanium oxide, germanium nitride, combinations of these, or the like. The dielectric layer 12 may be formed using a technique such as implantation (e.g., to form a buried oxide (BOX) layer) or using a suitable deposition technique such as chemical vapor deposition (CVD), atomic layer deposition (ALD), physical vapor deposition (PVD), combinations of these, or the like. However, any suitable material and method of manufacture may be used.

In some embodiments, the photonic layer 14 may be a semiconductor material such as silicon, germanium, silicon germanium, combinations of these, or the like. In other embodiments, the photonic layer 14 may comprise a dielectric material such as silicon nitride or the like, a III-V semiconductor material, lithium niobate materials, polymers, the like, or combinations thereof. The photonic layer 14 may be formed using a suitable technique, such as epitaxial growth, CVD, ALD, PVD, the like, or combinations thereof. Other materials or techniques are possible.

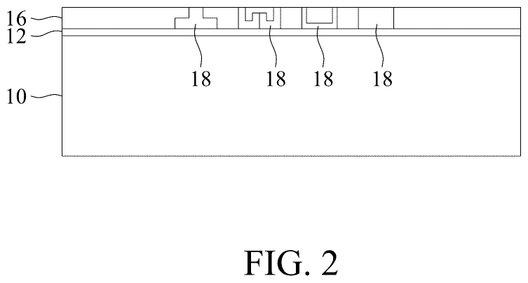

FIG. 2 illustrates the formation of photonic components 18 from the photonic layer 14, in accordance with some embodiments. In some embodiments, the photonic components 18 may include such devices or components as optical waveguides (e.g., ridge waveguides, rib waveguides, buried channel waveguides, diffused waveguides, etc.), couplers (e.g., grating couplers, edge couplers comprising a tip waveguide having a width in the range of about 1 nm to about 200 nm, etc.), directional couplers, optical modulators (e.g., germanium modulators, Mach-Zehnder silicon-photonic switches, microelectromechanical switches, micro-ring resonators, etc.), amplifiers, multiplexors, demultiplexors, optical-to-electrical converters (e.g., photodetectors, P-N junctions, or the like), electrical-to-optical converters, lasers (e.g., laser diodes), phase shifters, combinations of these, or the like. However, the photonic components 18 may comprise other devices structures, or components than these examples.

In some embodiments, the photonic components 18 may be formed by patterning the photonic layer 14 into the appropriate shapes for the photonic components 18. For example, photonic layer 14 may be patterned using one or more photolithographic masking and etching processes, though any suitable method of patterning the photonic layer 14 may be utilized. The patterning may expose portions of the dielectric layer 12. In some cases, additional processing steps may be performed to form some types of photonic components 18, such as additional implantation processes, deposition processes, and/or patterning processes. In some embodiments, one or more photonic components 18 may be formed by patterning the photonic layer 14 and then depositing another material on portions of the patterned photonic layer 14. For example, the formation of a photonic components 18 may comprise patterning a photonic layer 14 comprising silicon and then epitaxially growing a region of germanium on the patterned photonic layer 14, though other materials or process steps are possible.

Sill referring to FIG. 2, a dielectric layer 16 may be formed over the dielectric layer 12 and/or the photonic components 18, in accordance with some embodiments. The dielectric layer 16 may be, for example, a dielectric layer that separates the individual photonic components 18 from each other and from the overlying structures. Further, in some cases, the dielectric layer 16 can additionally serve as a cladding material that at least partially surrounds one or more photonic components 18. In some embodiments, the dielectric layer 16 may comprise silicon oxide, silicon nitride, germanium oxide, germanium nitride, combinations of these, or the like, which may be formed using suitable deposition techniques such as CVD, ALD, PVD, or the like. Other materials or deposition techniques are possible. In some embodiments, after depositing the dielectric layer 16, a planarization process (e.g., a chemical mechanical polishing (CMP) process, a grinding process, or the like) may be performed to planarize a top surface of the dielectric layer 16. In some embodiments, the planarization process may expose a top surface of one or more photonic components 18. In such embodiments, the top surfaces of the photonic components 18 and the top surfaces of the dielectric layer 16 may be level or coplanar (within process variations). In some embodiments, one or more photonic components 18 remain covered by the dielectric layer 16 after performing the planarization process.

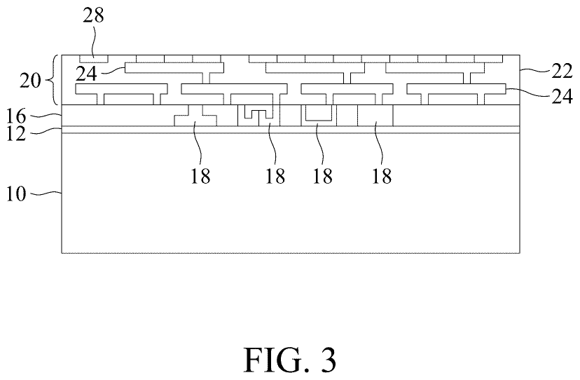

FIG. 3 illustrates the formation of an interconnect structure 20 over the photonic components 18, in accordance with some embodiments. The interconnect structure 20 includes dielectric layers 22 (not individually illustrated) with conductive features 24 formed in the dielectric layers 22, in some embodiments. The conductive features 24 allow for electrical communication within the optical bridge module 60. The conductive features 24 may comprise conductive lines, conductive vias, conductive pads, metallization patterns, redistribution layers, or the like that provide electrical interconnections and electrical routing within the optical bridge module 60. Conductive features 24 may be electrically connected to one or more photonic components 18, in some cases. The interconnect structure 20 may also comprise conductive pads 28 at a top surface of the interconnect structure 20, in some embodiments. The conductive pads 28 may be metal pads, bonding pads, or the like.

In some embodiments, the interconnect structure 20 is formed of alternating layers of dielectric material (e.g., dielectric layers 22) and conductive material (e.g., conductive features 24). The conductive features 24 may be formed using any suitable processes such as deposition, damascene, dual damascene, or the like. In particular embodiments, the interconnect structure 20 may have multiple layers of conductive features 24, but the precise number of layers of conductive features 24 may be dependent upon the design of the optical bridge module 60. The dielectric layers 22 may be, for example, insulating layers and/or passivating layers, and may comprise silicon oxide, silicon nitride, a polymer, the like, or a combination thereof. The conductive features 24 may include, for example, a metal or a metal alloy such as copper, silver, gold, tungsten, cobalt, ruthenium, aluminum, alloys thereof, combinations thereof, or the like. Other materials are possible.

In some embodiments, the conductive pads 28 are formed in the topmost dielectric layer 22 of the dielectric layers 22. In some embodiments, the conductive pads 28 electrically contact underlying conductive features 24. The conductive pads 28 may comprise one or more layers of conductive materials such as those described above for the conductive features 24, or the like. In some cases, the conductive pads 28 are considered part of the conductive features 24. Other types of conductive pads 28 are possible.

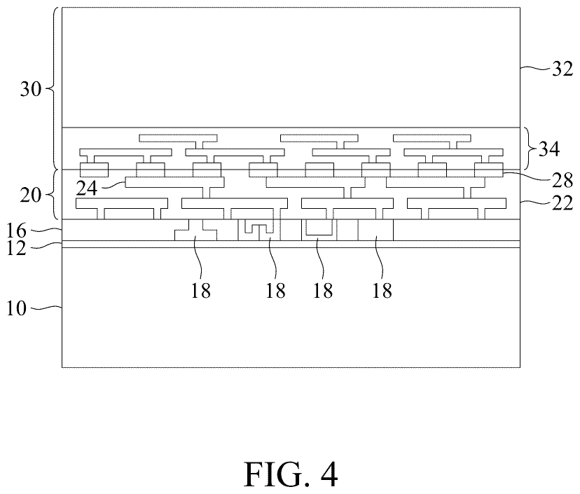

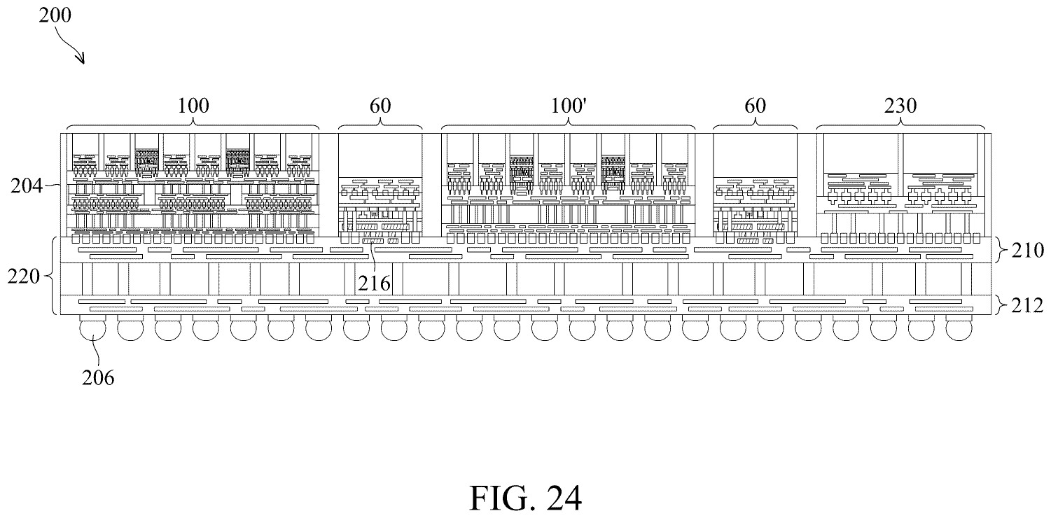

In FIG. 4, an electronic die 30 is bonded to the interconnect structure 20, in accordance with some embodiments. The electronic die 30 may comprise a substrate 32 and an interconnect structure 34 formed on one side of the substrate 32, in some embodiments. The substrate 32 may be similar to those described previously for the substrate 10, such as a silicon wafer or the like. In some embodiments, integrated circuits (not separately illustrated) may be formed in the substrate 32 using suitable techniques. For example, the electronic die 30 may include controllers, drivers, transimpedance amplifiers, transistors, other active devices, resistors, capacitors, other passive devices, the like, or combinations thereof. Accordingly, the electronic die 30 may be considered an electronic integrated circuit (EIC) structure or the like. In some embodiments, the integrated circuits may be configured to interface with the photonic components 18. For example, the integrated circuits may be configured to control the operation of the photonic components 18, to process electronic signals received from the photonic components 18, or the like. The integrated circuits may be configured to control high-frequency signaling of the photonic components 18 according to electrical signals (digital or analog) received from another module (e.g., a package module 100/100′ or module 230, see FIG. 24), in some embodiments. In this manner, an optical bridge module 60 may process or transmit electrical signals based on received optical signals and/or may process or transmit optical signals based on received electrical signals. In some embodiments, the electronic die 30 may provide Serializer/Deserializer (SerDes) functionality. In some embodiments, an electronic die 30 may comprise one or more processing devices, such as a Central Processing Unit (CPU or “xPU”), a Graphics Processing Unit (GPU), an Application-Specific Integrated Circuit (ASIC), a High-Performance Computing (HPC) die, a logic die, the like, or a combination thereof. An electronic die 30 may include one or more memory devices, which may be a volatile memory such as Dynamic Random-Access Memory (DRAM), Static Random-Access Memory (SRAM), High-Bandwidth Memory (HBM), another type of memory, or the like.

The interconnect structure 34 of the electronic die 30 may comprise conductive features formed in one or more dielectric layers. The conductive features may comprise conductive lines, conductive vias, conductive pads, metallization patterns, redistribution layers, or the like that provide electrical interconnections and electrical routing. In some embodiments, the interconnect structure 34 is formed of alternating layers of dielectric material and conductive material. The conductive features may be formed using any suitable processes such as deposition, damascene, dual damascene, or the like. In some cases, the conductive features may be formed using materials or techniques similar to those described previously for the interconnect structure 20.

In some embodiments, the interconnect structure 34 may include bond pads formed in a bonding layer, and the electronic die 30 is bonded to the interconnect structure 20 by dielectric-to-dielectric bonding and/or metal-to-metal bonding (e.g., direct bonding, fusion bonding, oxide-to-oxide bonding, hybrid bonding, or the like). In some embodiments, a bonding layer (e.g., an exposed dielectric layer) of the interconnect structure 34 is bonded to a bonding layer (e.g., an exposed dielectric layer) of the interconnect structure 20 using a dielectric-to-dielectric bonding process, and conductive pads of the interconnect structure 34 are bonded to corresponding conductive pads 28 of the interconnect structure 20 using a metal-to-metal bonding process. In some embodiments, the bonding process may be initiated by activating the bonding surfaces of the bonding layers of the interconnect structure 34 and the interconnect structure 20, which can facilitate bonding of the bonding surfaces. Activating the bonding surfaces may comprise, for example, a dry treatment, a wet treatment, a plasma treatment, exposure to an inert gas plasma, exposure to H 2, exposure to N₂, exposure to O₂, combinations thereof, or the like. For embodiments in which a wet treatment is used, an RCA cleaning process may be used, for example. In other embodiments, the activation process may comprise other types of treatments. After the activation process, the electronic die 30 is aligned and placed into physical contact with the interconnect structure 20. The electronic die 30 and the interconnect structure 20 are then subjected to a thermal treatment and contact pressure to bond respective bonding layers together with dielectric-to-dielectric bonding and bond the conductive pads of the electronic die 30 to the conductive pads 28 of the interconnect structure 20 with metal-to-metal bonding. In some embodiments, the resulting bonded structure is subsequently baked, annealed, pressed, or otherwise treated to strengthen or finalize the bond. This is an example, and other bonding processes are possible. In other embodiments, the electronic dies 30 may comprise conductive connectors (e.g. solder bumps or the like), and may be bonded to the interconnect structure 20 using these conductive connectors.

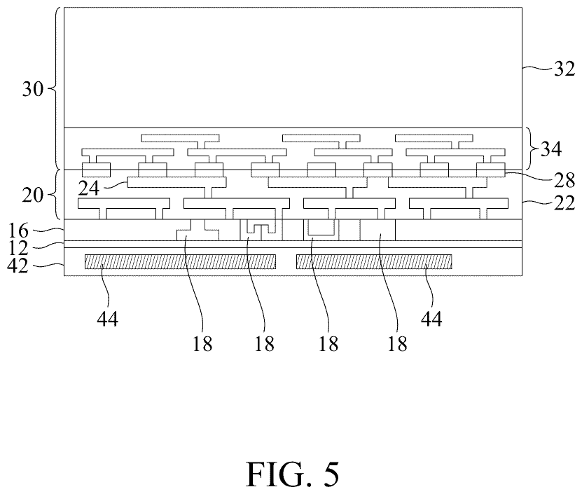

In FIG. 5, the substrate 10 is removed and waveguides 44 are formed, in accordance with some embodiments. The substrate 10 may be removed using a planarization process (e.g., a CMP process, a grinding process, or the like) and/or an etching process. In some embodiments, removing the substrate 10 exposes the dielectric layer 12. In some embodiments, removing the substrate 10 also thins the dielectric layer 12. In some embodiments, the dielectric layer 12 is used as a stop layer during removal of the substrate 10.

After removing the substrate 10, waveguides 44 are then formed over the dielectric layer 12, in accordance with some embodiments. The waveguides 44 may allow for optical communication within the optical bridge module 60 and may be optically coupled to photonic components 18. For example, waveguides 44 may receive optical signals from photonic component(s) 18 and/or transmit optical signals to photonic component(s) 18. FIG. 5 shows a single layer of waveguides 44 formed within a plurality of dielectric layers 42 (not individually illustrated), however, multiple layers of waveguides 44 may be formed in other embodiments. For example, one or more layers of waveguides 44 may be formed within multiple dielectric layers 42 (not individually illustrated). In some embodiments, a waveguide 44 may be optically coupled to an adjacent waveguide 44, to an overlying waveguide 44 of another layer, and/or to an underlying waveguide 44 of another layer. Waveguides 44 may be optically coupled using suitable techniques, such as using evanescent coupling, grating couplers, or other optical coupling techniques.

In some embodiments, a layer of waveguides 44 may be formed by depositing a waveguide material on a dielectric layer 42 and then patterning the waveguide material. In some embodiments, the waveguide material may be deposited on the dielectric layer 12 and thus the resulting waveguides 44 are formed on the dielectric layer 12. In other cases, the waveguide material is deposited on a previously deposited dielectric layer 42. The waveguide material may be a dielectric material such as silicon nitride, silicon oxide, silicon oxynitride, polymer, combinations of these, or the like. In other embodiments, the waveguide material may be a semiconductor material such as silicon, germanium, or the like. The waveguide material may be deposited using a suitable technique, such as ALD, PVD, or the like. The waveguide material may then be patterned using suitable photolithography and etching techniques to form a layer of waveguides 44. Another dielectric layer 42 may then be deposited on the waveguides 44. The steps of depositing a waveguide material, patterning the waveguide material to form a layer of waveguides 44, and then depositing a dielectric layer 42 over the layer of waveguides 44 may be repeated to form multiple layers of waveguides 44.

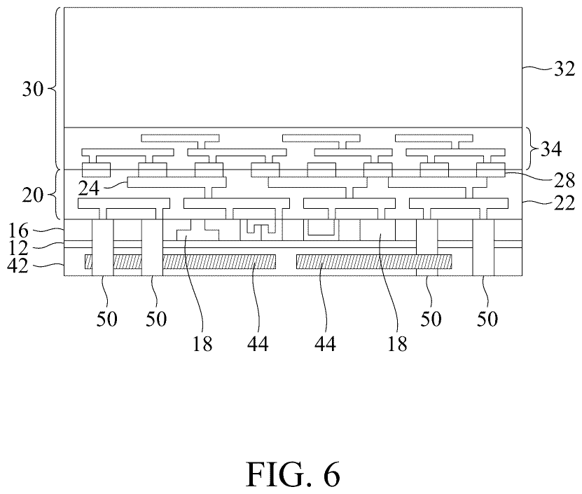

In FIG. 6, vias 50 are formed extending through the dielectric layer(s) 42, the dielectric layer 12, and the dielectric layer 16, in accordance with some embodiments. The vias 50 may physically and electrically contact conductive features 24 of the interconnect structure 20. In some embodiments, the vias 50 may extend into one or more of the dielectric layers 22 of the interconnect structure 20. The vias 50 may be formed, for example, by forming openings extending through the dielectric layer(s) 42, the dielectric layer 12, and the dielectric layer 16, and/or one or more dielectric layers 22 to expose surfaces of the conductive features 24. The openings may be formed using acceptable photolithography and etching techniques, such as by forming and patterning a photoresist and then performing an etching process using the patterned photoresist as an etching mask. The etching process may include, for example, a dry etching process and/or a wet etching process. A conductive material may then be deposited in the openings, thereby forming the vias 50. In some embodiments, a liner (not shown) may be deposited in the openings prior to forming the conductive material. The conductive material may comprise, for example, a metal or a metal alloy such as copper, silver, gold, tungsten, cobalt, aluminum, alloys thereof, or the like. A planarization process (e.g., a CMP process or a grinding process) may be performed to remove excess conductive, such that surfaces of the vias 50 and a dielectric layer 42 are level. Other materials or techniques are possible. In other embodiments, the vias 50 are formed at another stage of the manufacturing process than the embodiment shown.

In FIG. 7, bonding pads 52 and waveguides 48 are formed, in accordance with some embodiments. In some embodiments, a bonding layer 46 may be formed over the dielectric layer(s) 42, in accordance with some embodiments. The bonding pads 52 and waveguides 48 may be formed in the bonding layer 46. The bonding layer 46 may comprise one or more layers of suitable materials, such as silicon oxide, silicon oxynitride, the like, or a combination thereof.

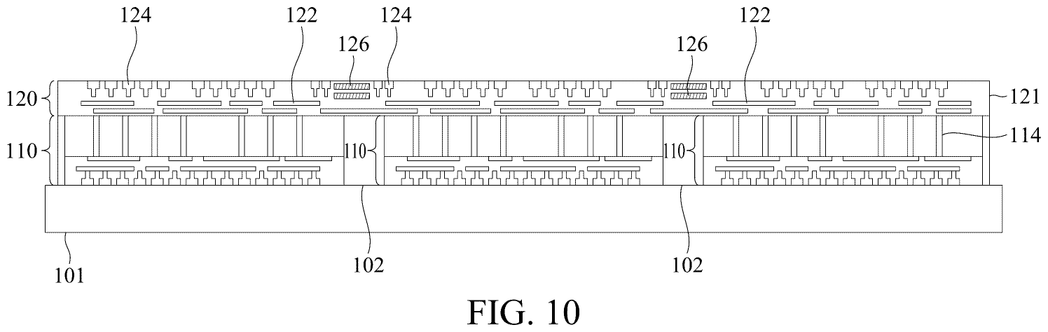

In some embodiments, one or more waveguides 48 may be formed over the dielectric layer(s) 42. The waveguides 48 are optically coupled to one or more overlying waveguides 44. The waveguides 48 may be optically coupled to one or more underlying waveguides of another structure to which the optical bridge module 60 has been attached, such as underlying waveguides 126 of the redistribution structure 120 (see FIG. 10). The waveguides 48 may be similar to the waveguides 44, and may be formed using similar materials or techniques. For example, a waveguide material may be deposited over the dielectric layer(s) 42 and then patterned to form the waveguides 48. The bonding layer 46 may then be deposited over the waveguides 48. In some embodiments, the bonding layer 46 may be planarized (e.g. using a CMP or grinding process) to expose the waveguides 48. In other embodiments, the waveguides 48 may remain covered by the bonding layer 46 after planarization.

In some embodiments, bonding pads 52 may be formed in the bonding layer 46. The bonding pads 52 may be similar to the conductive pads 28 and may be formed using similar materials or techniques. For example, openings may be patterned in the bonding layer 46 to expose the vias 50 using acceptable photolithography and etching techniques, and then the material of the bonding pads 52 may be deposited in the openings. In some embodiments, a planarization process (e.g., a CMP or grinding process) may be performed to remove excess material, and top surfaces of the bonding pads 52 and the bonding layer 46 may be substantially level or coplanar after planarization.

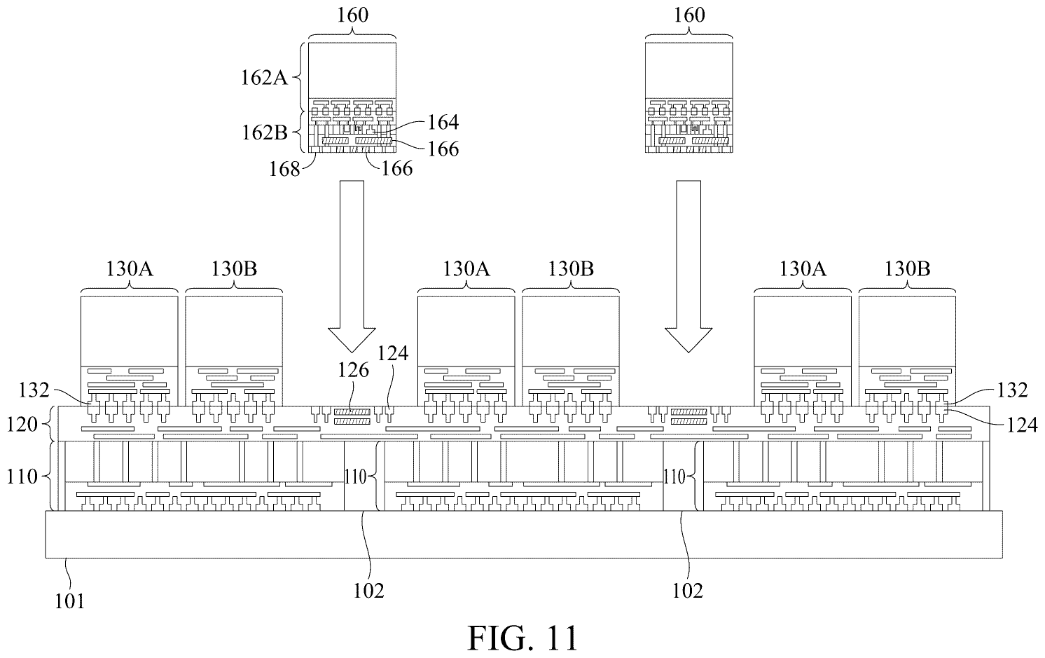

In this manner, an optical bridge module 60 may be formed, in accordance with some embodiments. In some embodiments, multiple optical bridge modules 60 may be formed on a single substrate 10 and then singulated into individual optical bridge modules 60. In some cases, the interconnect structure 20, photonic components 18, waveguides 44/48, vias 50, and associated dielectric layers may be considered a photonic integrated circuit (PIC) structure 31. In this manner, the optical bridge module 60 may be considered to be an EIC structure 30 bonded to a PIC structure 31, in some cases. The optical bridge module 60 described for FIGS. 1-7 is an example, and other process steps, materials, configurations, or arrangements are possible in other optical bridge modules 60. For example, the electronic die 30 may be bonded at a different process step than shown, or the number or configuration of conductive features and/or waveguides may be different than shown. In some embodiments, an optical bridge structure similar to the optical bridge module 60 described above may be formed for module-level optical communication (e.g., within a module). For example, see the optical bridge component 160, described below for FIG. 11. All suitable variations are considered within the scope of the present disclosure.

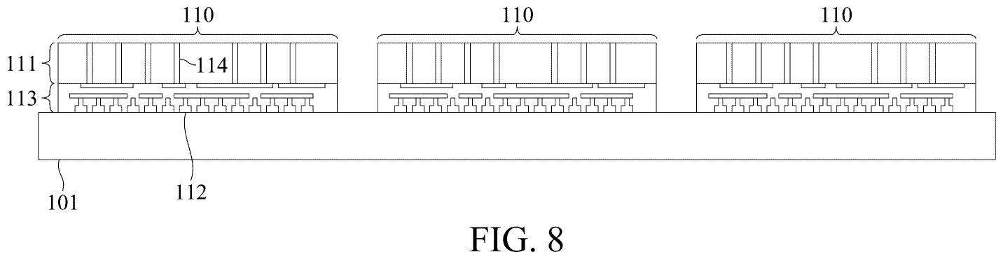

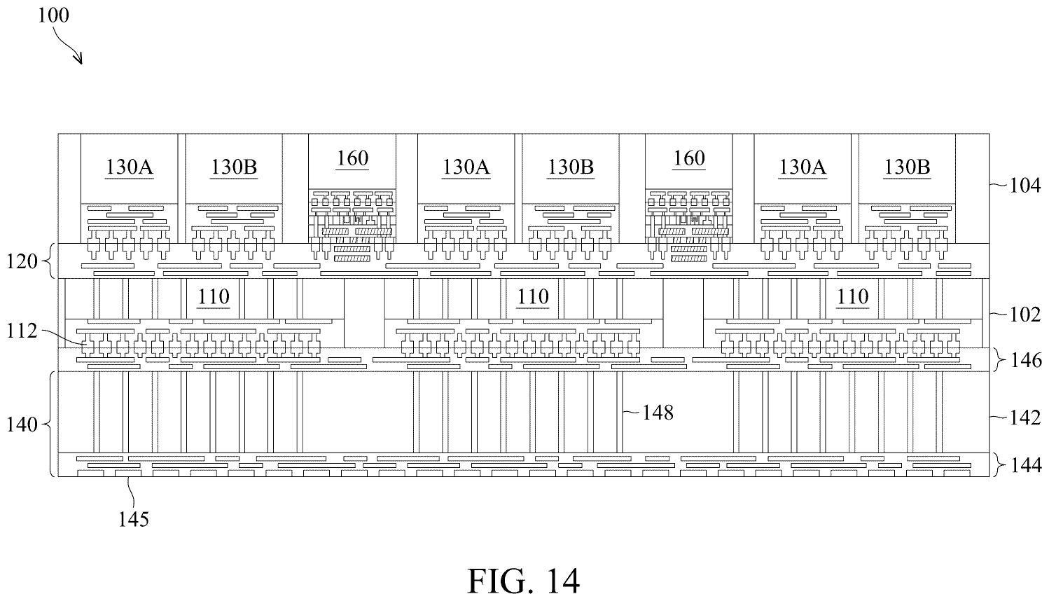

FIGS. 8 through 14 illustrate intermediate stages in the manufacturing of a package module 100 (see FIG. 14), in accordance with some embodiments. In FIG. 8, a plurality of first components 110 are attached to a first carrier 101, in accordance with some embodiments. The first carrier 101 may be a supporting substrate, wafer, panel, or the like that is formed of any suitable materials, such as a semiconductor (e.g., silicon or the like), a glass, an oxide material (e.g., silicon oxide, aluminum oxide, or the like), a plastic, a polymer, an organic material, a metal, a film, the like, or a combination thereof. The first components 110 may be attached to the first carrier 101 using an adhesive, a die attach film (DAF), or the like. FIG. 8 illustrates three first components 110 attached to the first carrier 101, but any suitable number of first components 110 may be attached to the first carrier 101 in other embodiments.

The first components 110 may comprise, for example, a chip, a die, a system-on-chip (SoC) device, a system-on-integrated-circuit (SoIC) device, the like, or a combination thereof. The first components 110 attached to the same first carrier 101 may be similar or different. In some embodiments, the first components 110 comprise logic dies, memory dies, input-output (I/O) dies, Integrated Passive Devices (IPDs), or the like, or combinations thereof. For example, the first components 110 may comprise logic dies such as Central Processing Unit (CPU or xPU) dies, Graphic Processing Unit (GPU) dies, mobile application dies, high performance computing (HPC) dies, Micro Control Unit (MCU) dies, BaseBand (BB) dies, Application processor (AP) dies, Application-Specific Integrated Circuit (ASIC) dies, or the like. The first components 110 may comprise memory dies such as Static Random-Access Memory (SRAM) dies, Dynamic Random-Access Memory (DRAM) dies, High-Bandwidth Memory (HBM) dies, or the like. Other types or configurations of first components 110 are possible.

In some embodiments, the first components 110 comprise bonding pads 112 and through vias 114. The bonding pads 112 may be formed at a first side of a first component 110, and may be formed within a bonding layer (not individually illustrated) of the first component 110. Surfaces of the bonding pads 112 and the bonding layer may be substantially coplanar. The bonding pads 112 allow physical and electrical connection to be made between a first component 110 and another structure at the first side of the first component 110. The bonding pads 112 may be part of an interconnect structure 113 of the first component 110, in some embodiments. The through vias 114 of a first component 110 may extend through a portion of the first component 110 to a second side of the first component 110 opposite the first side. For example, the through vias 114 may extend through a substrate 111 of the first component 110. The through vias 114 allow physical and electrical connection to be made between a first component 110 and another structure at the second side of the first component 110. The through vias 114 may be electrically coupled to an interconnect structure 113 of the first component 110, in some embodiments. In some embodiments, the through vias 114 are not exposed at the second side of a first component 110 and are covered by portions of the substrate 111. In other embodiments, the first components 110 may have different configurations, functionalities, features, or arrangements than described or shown.

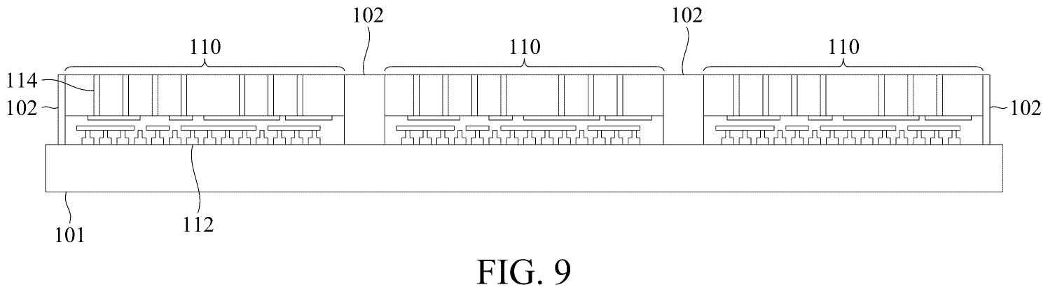

In FIG. 9, an encapsulant 102 is formed on and around the first components 110, in accordance with some embodiments. After formation, the encapsulant 102 encapsulates the first components 110. The encapsulant 102 may be a molding compound, an epoxy, a polymer, a composite material, a dielectric material, or the like. In some embodiments, the encapsulant 102 is applied by deposition, spin-on, compression molding, transfer molding, or the like. The encapsulant 102 may be formed over the first carrier 101 such that the first components 110 are buried or covered. The encapsulant 102 is further formed in gap regions between neighboring first components 110. The encapsulant 102 may be applied in liquid or semi-liquid form and then subsequently cured.

In some embodiments, a planarization process is performed on the encapsulant 102 to expose the through vias 114 of the first components 110. In embodiments in which through vias 114 are covered by the substrate 111, the planarization process may also remove material of the substrate 111 until the through vias 114 are exposed. Top surfaces of the through vias 114, the substrates 111, and the encapsulant 102 may be substantially level or coplanar (within process variations) after performing the planarization process. The planarization process may comprise, for example, a chemical-mechanical polish (CMP) process, a grinding process, an etching process, or the like. In some embodiments, the planarization may be omitted, for example, if the through vias 114 are already exposed.

In FIG. 10, a redistribution structure 120 is formed over the first components 110 and over the encapsulant 102, in accordance with some embodiments. FIG. 10 illustrates the redistribution structure 120 formed over the front side of the first components 110, but the redistribution structure 120 may be formed over the back side of the first components 110 in other embodiments. The redistribution structure 120 comprises conductive features 122, conductive pads 124, and waveguides 126 formed in a plurality of dielectric layers 121 (not individually illustrated). The conductive features 122 and conductive pads 124 provide electrical interconnections between first components 110, second components 130A-B (see FIG. 11), and/or optical bridge components 160 (see FIG. 11) that are connected to the redistribution structure 120. The waveguides 126 enable long-distance optical communication within the redistribution structure 120 in conjunction with the optical bridge modules 60, described in greater detail below.

The conductive features 122 may include one or more layers of conductive lines, conductive vias, conductive pads, or the like, which may be considered metallization patterns or redistribution layers in some cases. Some conductive features 122 are electrically coupled to through vias 114 of first components 110. The conductive features 122 may be formed using any suitable process, such as deposition, plating, damascene, dual damascene, or the like. The conductive features 122 may be formed of conductive material(s) such as copper, silver, gold, tungsten, cobalt, ruthenium, aluminum, alloys thereof, combinations thereof, or the like, though other materials are possible. In some embodiments, the dielectric layers 121 may comprise suitable dielectric materials, such as silicon oxide, silicon oxynitride, silicon nitride, or the like. The number of layers of conductive features 122 may be different than shown, and the conductive features 122 may have a different configuration or arrangement than shown.

In some embodiments, the conductive pads 124 are formed in the topmost dielectric layer 121 of the dielectric layers 121, which may be a bonding layer. The conductive pads 124 are electrically coupled to underlying conductive features 122. In some cases, the conductive pads 124 may also be considered conductive features 122 of the redistribution structure 120. In some embodiments, the redistribution structure 120 is substantially free of active and passive devices.

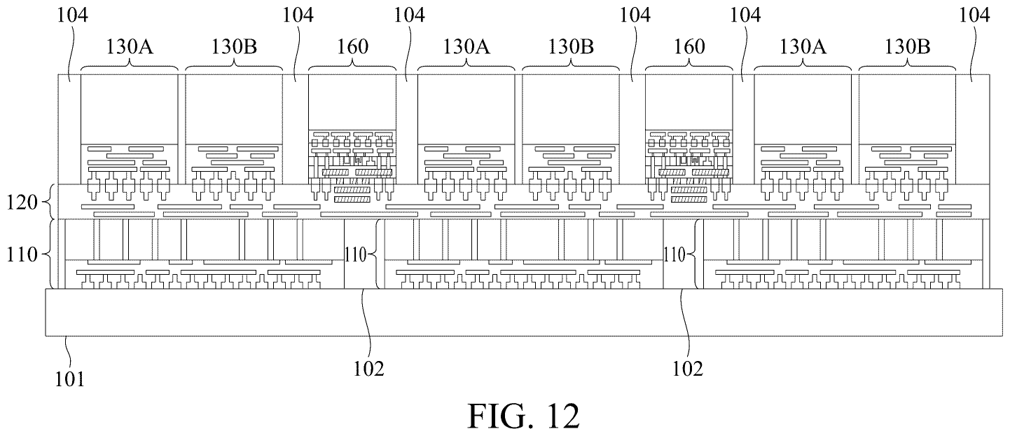

As shown in FIG. 10, the redistribution structure 120 also comprises one or more layers of waveguides 126, in accordance with some embodiments. The waveguides 126 may be formed using materials or techniques similar to those described previously for the waveguides 44 or 48 of the optical bridge module 60 (see FIG. 7). For example, in some embodiments, a layer of waveguides 126 may be formed by depositing a waveguide material on a dielectric layer 121 and then patterning the waveguide material. The waveguide material may be a dielectric material such as silicon nitride, silicon oxide, silicon oxynitride, polymer, combinations of these, or the like. In other embodiments, the waveguide material may be a semiconductor material such as silicon, germanium, or the like. A waveguide 126 may be optically coupled to an overlying or underlying waveguide 126 of another layer of waveguides 126. A waveguide 126 of the topmost layer of waveguides 126 may be optically coupled to an overlying structure. For example, a waveguide 126 may be optically coupled to a waveguide 166 of an overlying optical bridge component 160 (see FIG. 12). FIG. 10 shows two layers of waveguides 126, but the number of layers of waveguides 126 may be different than shown. The waveguides 126 may have a different configuration or arrangement than shown.

In FIG. 11, a plurality of second components 130A-B and a plurality of optical bridge components 160 are bonded to the redistribution structure 120, in accordance with some embodiments. In this manner, the redistribution structure 120 may have first components 110 attached to its back side and second components 130A-B and optical bridge components 160 attached to its front side. FIG. 11 illustrates the second components 130A-B already placed on the redistribution structure 120, and the optical bridge components 160 prior to placement on the redistribution structure 120. However, the second components 130A, the second components 130B, and the optical bridge components 160 may be placed on the redistribution structure 120 in any suitable order. One or more bonding processes may be used to bond the second components 130A-B and the optical bridge components 160 to the redistribution structure 120, described in greater detail below. In some cases, a single bonding process may be used to bond placed second components 130A-B and placed optical bridge components 160 to the redistribution structure 120 simultaneously. FIG. 12, described in greater detail below, shows the second components 130A-B and the optical bridge components 160 bonded to the redistribution structure 120.

The second components 130A-B may include, for example, a chip, a die, a system-on-chip (SoC) device, a system-on-integrated-circuit (SoIC) device, the like, or a combination thereof. The second components 130A-B attached to the same redistribution structure 120 may be similar or different types of components. While FIG. 11 shows two types of second components 130A and 130B, in other embodiments, only one type of second component 130 or more than two types of second components 130 may be present. In some embodiments, the second components 130A-B comprise logic dies, memory dies, input-output (I/O) dies, Integrated Passive Devices (IPDs), or the like, or combinations thereof. For example, the second components 130A-B may comprise logic dies such as Central Processing Unit (CPU or xPU) dies, Graphic Processing Unit (GPU) dies, mobile application dies, high performance computing (HPC) dies, Micro Control Unit (MCU) dies, BaseBand (BB) dies, Application processor (AP) dies, Application-Specific Integrated Circuit (ASIC) dies, or the like. The second components 130A-B may comprise memory dies such as Static Random-Access Memory (SRAM) dies, Dynamic Random-Access Memory (DRAM) dies, High-Bandwidth Memory (HBM) dies, or the like. Other types or configurations of second components 130A-B are possible.

In some embodiments, the second components 130A-B comprise bonding pads 132. The bonding pads 132 may be formed within a bonding layer (not individually illustrated) of the second components 130A-B. Surfaces of the bonding pads 132 and the bonding layer may be substantially coplanar. The bonding pads 132 may be part of an interconnect structure of a second component 130A-B, in some cases. In some embodiments, the second components 130A-B may be attached to the redistribution structure 120 by bonding the bonding pads 132 of the second components 130A-B to corresponding conductive pads 124 of the redistribution structure 120 using metal-to-metal bonding, described in greater detail below.

In some embodiments, each second component 130A-B is attached to the redistribution structure 120 over a corresponding first component 110. A second component 130A-B may partially or fully overlap (e.g., laterally or horizontally overlap) its corresponding first component 110. In some embodiments, the lateral dimensions (e.g., length and/or width) of one or more second components 130A-B may be smaller than the lateral dimensions of the corresponding first component 110. In other words, the footprint (e.g. lateral area) of one or more second components 130A-B may be smaller than the footprint of the corresponding first component 110. In some embodiments, one or more second components 130A-B may fully overlap the corresponding first component 110 such that the first component 110 laterally protrudes beyond the edges of the second component(s) 130A-B. In other embodiments, the lateral dimensions of a second component 130A-B may be about the same or greater than the lateral dimensions of its corresponding first component 110. In some embodiments, a first component 110 may have one corresponding second component 130 or more than two corresponding second components 130.

In some embodiments, the second components 130A-B are different types of components than the first components 110. As a non-limiting example, a second component 130A may be a memory die and the corresponding first package component 110 may be a logic die. This is an example, and any suitable combinations of component types are possible. Using first components 110 and second components 130A-B having different functionalities in this manner can reduce package size, improve efficiency, and improve performance.

In some embodiments, the optical bridge components 160 may be structures, packages, modules, or the like that provide functionality similar to the optical bridge modules 60. The optical bridge components 160 may be formed using similar materials or techniques as described above for the optical bridge modules 60, and may have some similar features as the optical bridge modules 60. For example, in some embodiments, an optical bridge component 160 may comprise an electronic integrated circuit (EIC) structure 162A bonded to a photonic integrated circuit (PIC) structure 162B. The EIC structure 162A may comprise or be similar to the electronic die 30 described previously. The PIC structure 162B may comprise photonic components 164 and waveguides 166. The photonic components 164 may be similar to the photonic components 18 described previously, and the waveguides 166 may be similar to the waveguides 44/48 described previously. The EIC structure 162A may be electrically coupled to the photonic components 164. The optical bridge components 160 may also comprise bonding pads 168, which may be similar to the bonding pads 52 described previously. The optical bridge components 160 may have different sizes, configurations, materials, formation steps, and/or features than the optical bridge modules 60. For example, in some cases, an optical bridge component 160 may have a width and/or thickness that is less than a width and/or thickness of an optical bridge module 60.

In some embodiments, the optical bridge components 160 may be attached to the redistribution structure 120 by bonding the bonding pads 168 of the optical bridge components 160 to corresponding conductive pads 124 of the redistribution structure 120 using metal-to-metal bonding. The optical bridge components 160 may be attached to the redistribution structure 120 also using dielectric-to-dielectric bonding, in some embodiments. After attaching the optical bridge components 160 to the redistribution structure 120, waveguides 166 of the optical bridge components 160 may be optically coupled to waveguides 126 of the redistribution structure 120. In this manner, optical signals may be transmitted between the optical bridge components 160 and the redistribution structure 120. For example, an optical bridge component 160 may receive optical signals from a waveguide 126 or may transmit optical signals into a waveguide 126.

In some embodiments, an optical bridge component 160 may be arranged between two neighboring second components 130A-B, as shown in FIG. 12. In some embodiments, an optical bridge component 160 may be placed such that it overlaps two neighboring first components 110, as shown in FIG. 12. In some embodiments, an optical bridge component 160 may be placed laterally between two neighboring first components 110. In some embodiments, an optical bridge component 160 may electrically communicate with one or more adjacent first components 110 and/or second components 130A-B. For example, in some embodiments, an optical bridge component 160 may receive electrical signals from an associated first component 110 and/or an associated second component 130A-B (e.g., “associated component(s) 110/130”) and may transmit optical signals into a waveguide 126 based on the electrical signals. As another example, an optical bridge component 160 may receive optical signals from a waveguide 126 and may transmit electrical signals to an associated component 110/130 based on the optical signals.

In some embodiments, the second components 130A-B and the optical bridge components 160 may be bonded to the redistribution structure 120 using dielectric-to-dielectric bonding and metal-to-metal bonding (e.g., using fusion bonding). The second components 130A-B and the optical bridge components 160 may be bonded using one or more of the same process steps or may be bonded using separate process steps. The second components 130A-B and the optical bridge components 160 may be bonded simultaneously or in any suitable order or sequence. The bonding process may be similar to that described previously for FIG. 4. For example, in some embodiments, bonding layers of the second components 130A-B and bonding layers of the optical bridge components 160 are bonded to a bonding layer of the redistribution structure 120 using a dielectric-to-dielectric bonding process, and bonding pads 132 of the second components 130A-B and bonding pads 168 of the optical bridge components 160 are bonded to corresponding conductive pads 124 of the redistribution structure 120 using a metal-to-metal bonding process.

In FIG. 12, an encapsulant 104 is formed on and around the second components 130 and the optical bridge components 160, in accordance with some embodiments. After formation, the encapsulant 104 encapsulates the second components 130 and the optical bridge components 160. The encapsulant 104 may be a molding compound, an epoxy, a polymer, a composite material, a dielectric material, or the like, and may be similar to the encapsulant 102 in some cases. In some embodiments, the encapsulant 104 is applied by deposition, spin-on, compression molding, transfer molding, or the like. The encapsulant 104 may be formed over the redistribution structure 120 such that the second components 130 and/or the optical bridge components 160 are buried or covered. The encapsulant 104 may be applied in liquid or semi-liquid form and then subsequently cured.

In some embodiments, a planarization process is performed on the encapsulant 104 to expose the second components 130 and/or the optical bridge components 160. Top surfaces of the second components 130, the optical bridge components 160, and/or the encapsulant 104 may be substantially level or coplanar (within process variations) after performing the planarization process. The planarization process may comprise, for example, a CMP process, a grinding process, an etching process, or the like. In some embodiments, the planarization process may be omitted.

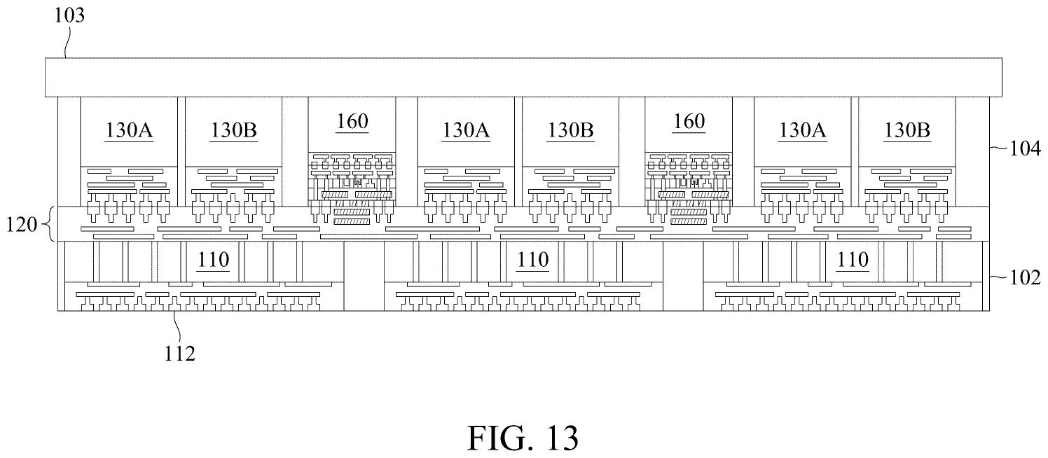

In FIG. 13, a second carrier 103 is attached to the structure and the first carrier 101 is removed, in accordance with some embodiments. The second carrier 103 is attached to the front side of the structure, and thus may be attached to the second components 130, the optical bridge components 160, and/or the encapsulant 104 in some cases. The second carrier 103 may be similar to the first carrier 101, and may be attached using an adhesive or other suitable technique. After attachment of the second carrier 103, the first carrier 101 is removed from the back side of the structure. Removing the first carrier 101 may expose the back sides of the first components 110 and the encapsulant 102, as shown in FIG. 13.

In FIG. 14, an interposer 140 is attached to the back side of the structure and the second carrier 103 is removed to form a package module 100, in accordance with some embodiments. The waveguides 126 allow optical communication between components 110/130, and the optical bridge components 160 provide interfacing and processing of electrical signals and optical signals for the components 110/130. The waveguides 126 of the redistribution structure 120 may extend from one optical bridge component 160 to another optical bridge component 160.

In some embodiments, the interposer 140 is bonded to the first components 110 using dielectric-to-dielectric bonding and metal-to-metal bonding. For example, bonding pads 112 of the first components 110 may be bonded to corresponding conductive pads (not separately labelled) of the interposer 140 using metal-to-metal bonding. In this manner, the interposer 140 is physically and electrically connected to the first components 110. In some embodiments, the interposer 140 comprises a substrate 142, a back side interconnect structure 144 on the back side of the substrate 142, a front side interconnect structure 146 on the front side of the substrate 142, and through vias 148 extending through the substrate 142. In other embodiments, the back side interconnect structure 144 or the front side interconnect structure 146 is not present. The interposer 140 shown is an example, and the interposer 140 may have another configuration in other embodiments. The interposer 140 may be substantially free of active and/or passive devices, in some embodiments.

The substrate 142 may be a semiconductor substrate (e.g., a silicon wafer) or another type of substrate, such as those described previously for the substrate 10 (see FIG. 1). In some embodiments, the substrate 142 may comprise an organic core or the like. Each interconnect structure 144/146 comprises one or more layers of conductive features formed in one or more dielectric layers (not individually illustrated). The conductive features may include conductive lines, conductive vias, conductive pads, metallization patterns, redistribution layers, or the like, which may be formed using any suitable technique such as deposition, damascene, dual damascene, or the like. In some embodiments, the front side interconnect structure 146 may comprise conductive pads that are bonded to corresponding bonding pads 112 of the first components 110, as mentioned above. In some embodiments, the back side interconnect structure 144 may comprise bonding pads 145. In some embodiments, the topmost dielectric layer of the front side interconnect structure 146 is a bonding layer that is bonded to bonding layers of the first components 110 using dielectric-to-dielectric bonding. The through vias 148 of the interposer 140 extend through the substrate 142 and electrically connect the back side interconnect structure 144 to the front side interconnect structure 146. Other configurations of the back side interconnect structure 144, the front side interconnect structure 146, and/or the through vias 148 are possible.

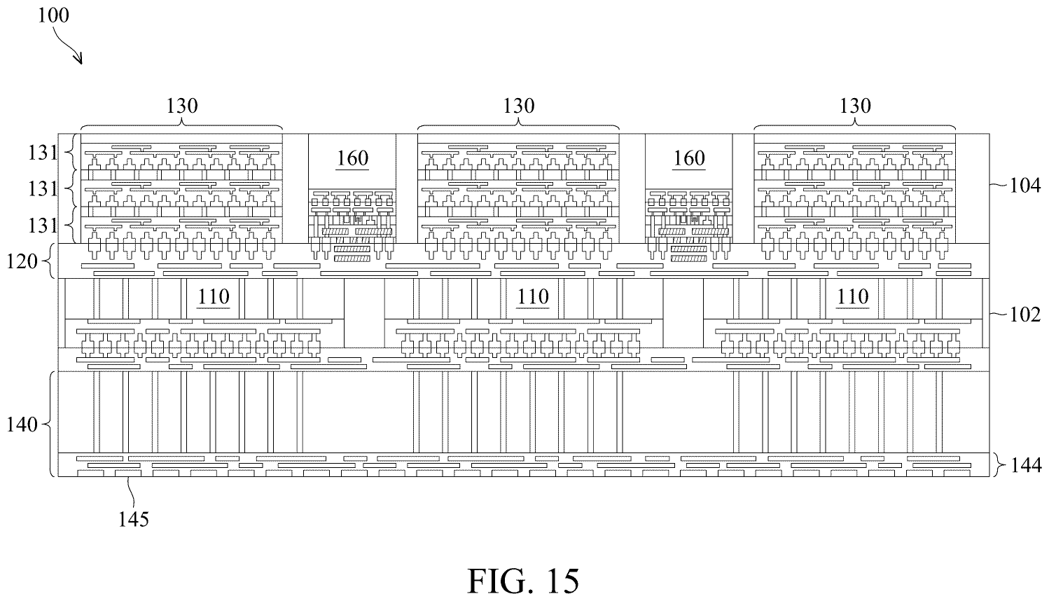

In this manner, a package module 100 may be formed, though other package modules 100 having other configurations are possible. As an example, FIG. 15 illustrates a package module 100, in accordance with some embodiments. The package module 100 of FIG. 15 is similar to the package module of FIG. 14, except that the second components 130 are stacked structures. For example, the second components 130 of FIG. 15 comprise three chiplets 131 that are bonded into a single stacked structure. The chiplets 131 may be dies, chips, SoIC devices, or the like. Other numbers of chiplets 131 or configurations of stacked structures are possible. As an example, the second components 130 may be High-Bandwidth Memory (HBM) devices, in some embodiments. Other types of stacked second components 130 are possible.

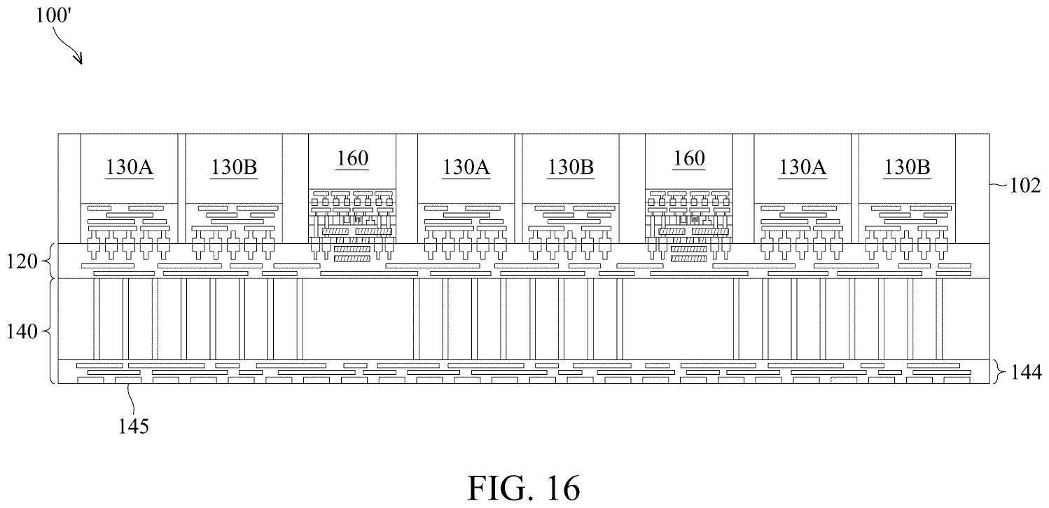

As another example, FIG. 16 illustrates a package module 100′, in accordance with some embodiments. The package module 100′ of FIG. 16 is similar to the package module 100 of FIG. 15, except that the first components 110, the second components 130, and the optical bridge components 160 are all attached to the same side of the redistribution structure 120. The redistribution structure 120 may be formed on or bonded to the front side of the interposer 140. The interposer 140 may or may not comprise a front side interconnect structure 146. These are examples of package modules, and other package modules are possible.

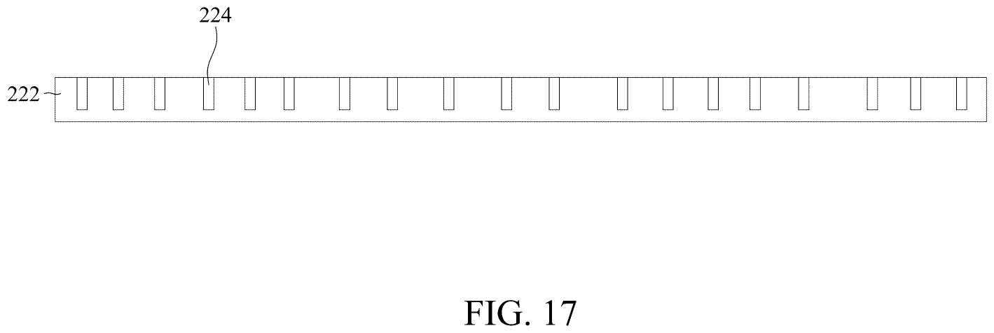

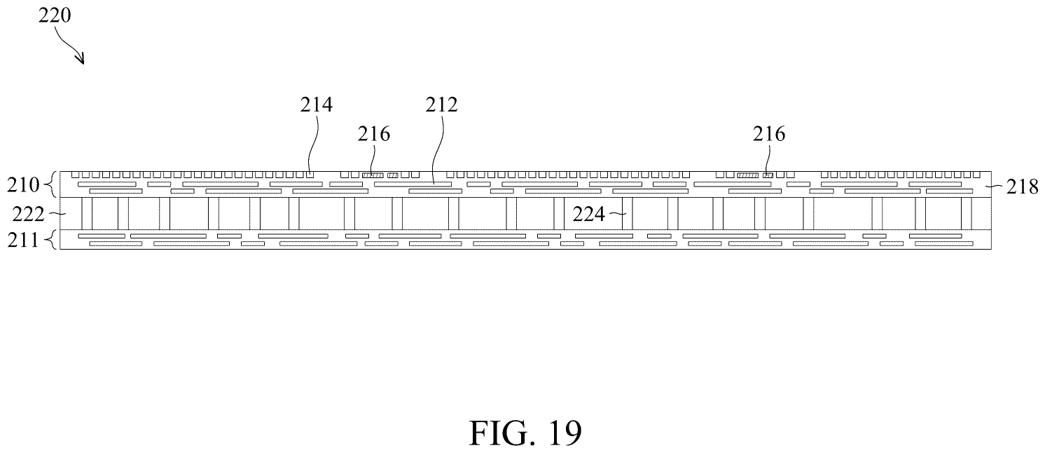

FIGS. 17-19 are cross-sectional views of intermediate stages in the manufacturing of an interposer structure 220 (see FIG. 19), in accordance with some embodiments. The interposer structure 220 comprises a front side interconnect structure 210 on the front side of a substrate 222 and a back side interconnect structure 211 on the back side of a substrate 222, in accordance with some embodiments. The front side interconnect structure 210 comprises conductive features 212 and waveguides 216, described in greater detail below. In other embodiments, the back side interconnect structure 211 is not formed. In some cases, the interposer structure 220 may be considered to be an interposer wafer, a composite wafer, or the like.

The substrate 222 may be a wafer, such as a silicon wafer, in some embodiments. Other substrates, such as a silicon-on-insulator (SOI) substrate, a multi-layered substrate, or a gradient substrate may also be used. The substrate 222 may be doped (e.g., with a p-type or an n-type dopant) or undoped. In some embodiments, the semiconductor material of the substrate 222 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In other embodiments, the substrate 222 may be a dielectric material such as silicon oxide, glass, ceramic, plastic, or any other suitable material that allows for structural support of overlying devices. For example, the substrate 222 may be a panel, a glass substrate, an organic substrate, a redistribution structure, an interconnect substrate, a core substrate, a printed circuit board (PCB), or the like. In some embodiments, multiple interposer structures 220 may be formed on a single substrate 222 and then may be subsequently singulated into individual interposer structures 220 or individual packages. In some embodiments, active devices (e.g., transistors, diodes, or the like), passive devices (e.g. capacitors, resistors, or the like), integrated circuits, and/or the like may be formed in the substrate 222. The substrate 222 may be free of passive or active devices, in other embodiments.

In some embodiments, the substrate 222 comprises through vias 224 extending partially or fully into the substrate 222. The through vias 224 are electrically connected to the subsequently-formed front side interconnect structure 210 and back side interconnect structure 211. The through vias 224 may be formed, for example, by forming openings extending into the substrate 222. The openings may be formed using acceptable photolithography and etching techniques, such as by forming and patterning a photoresist and then performing an etching process using the patterned photoresist as an etching mask. The etching process may include, for example, a dry etching process and/or a wet etching process. A conductive material may then be formed in the openings, thereby forming the through vias 224. In some embodiments, a liner (not shown) may be deposited in the openings prior to forming the conductive material. The conductive material may comprise, for example, a metal or a metal alloy such as copper, silver, gold, tungsten, cobalt, aluminum, alloys thereof, or the like. A planarization process (e.g., a CMP process or a grinding process) may be performed to remove excess conductive material along the surface of the substrate 222 such that surfaces of the through vias 224 and the substrate 222 are level. Other materials or techniques are possible.

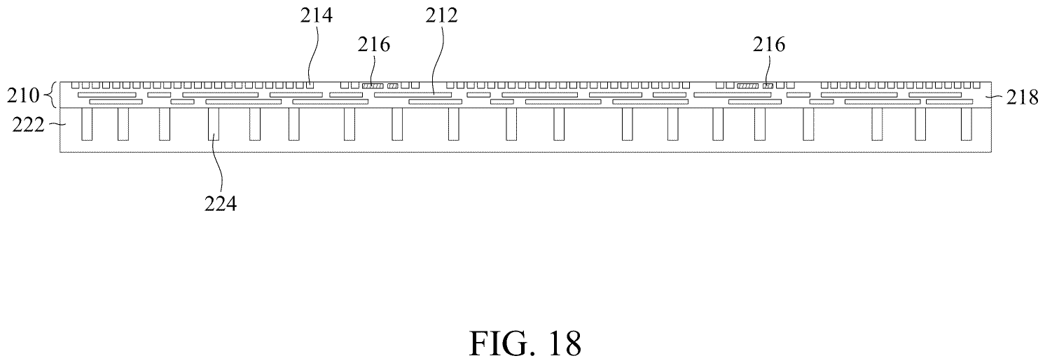

In FIG. 18, the front side interconnect structure 210 is formed over the substrate 222, in accordance with some embodiments. The front side interconnect structure 210 comprises one or more layers of conductive features 212 and one or more layers of waveguides 216 formed in one or more dielectric layers 218 (not individually illustrated), in some embodiments. The conductive features 212 may comprise conductive lines, conductive vias, conductive pads, metallization patterns, redistribution layers, or the like that provide electrical interconnections and electrical routing. In some embodiments, the conductive features 212 comprise conductive pads 214 at a top surface of the front side interconnect structure 210, such as in a top dielectric layer 218. In some embodiments, the front side interconnect structure 210 may have multiple layers of conductive features 212, but the precise number of layers of conductive features 212 may be dependent upon the design of the front side interconnect structure 210. The conductive features 212 may be formed using any suitable techniques such as deposition, damascene, dual damascene, or the like. The conductive features 212 may include, for example, a metal or a metal alloy such as copper, silver, gold, tungsten, cobalt, ruthenium, aluminum, alloys thereof, combinations thereof, or the like. In some cases, the conductive features 212 or conductive pads 214 may be formed using materials or techniques similar to those described previously for the redistribution structure 120. Other materials or techniques are possible.

Acceptable dielectric materials for the dielectric layers 218 include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The dielectric layers 218 may be formed using any suitable techniques. In some embodiments, the front side interconnect structure 210 may have multiple dielectric layers 218, but the precise number of dielectric layers 218 may be dependent upon the design of the front side interconnect structure 210. In some cases, the dielectric layers 121 may be formed using materials or techniques similar to those described previously for the redistribution structure 120. Other materials or techniques are possible.

As shown in FIG. 18, the front side interconnect structure 210 also comprises one or more layers of waveguides 216, in accordance with some embodiments. The waveguides 216 may be formed using materials or techniques similar to those described previously for the waveguides 44 or 48 of the optical bridge module 60 (see FIG. 7) or the waveguides 126 of the redistribution structure 120. For example, in some embodiments, a layer of waveguides 216 may be formed by depositing a waveguide material on a dielectric layer 218 and then patterning the waveguide material. The waveguide material may be a dielectric material such as silicon nitride, silicon oxide, silicon oxynitride, polymer, combinations of these, or the like. In other embodiments, the waveguide material may be a semiconductor material such as silicon, germanium, or the like. A waveguide 216 may be optically coupled to an overlying or underlying waveguide 216 of another layer of waveguides 216. A waveguide 216 of the topmost layer of waveguides 216 may be optically coupled to an overlying structure. For example, a waveguide 216 may be optically coupled to a waveguide 48 of an overlying optical bridge module 60 (see FIG. 24). FIG. 18 shows one layer of waveguides 216, but the number of layers of waveguides 216 may be different than shown. The waveguides 216 may have a different configuration or arrangement than shown. In some cases, the front side interconnect structure 210 may be considered to be a composite redistribution structure or the like.

In FIG. 19, the back side interconnect structure 211 is formed on the substrate 222 to form the interposer structure 220, in accordance with some embodiments. Prior to forming the back side interconnect structure 211, the back side of the substrate 222 may be thinned to expose the through vias 224. The thinning may be performed using an etching process, a CMP process, a grinding process, the like, or a combination thereof. The back side interconnect structure 211 may comprise one or more layers of conductive features formed in one or more dielectric layers (not individually illustrated). The conductive features and dielectric layers of the back side interconnect structure 211 may be similar to the conductive features 212 and dielectric layers 218 of the front side interconnect structure 210, and may be formed using similar materials or techniques. In some embodiments, the back side interconnect structure 211 may have multiple layers of conductive features or dielectric layers, but the precise number may be dependent upon the design of the back side interconnect structure 211.

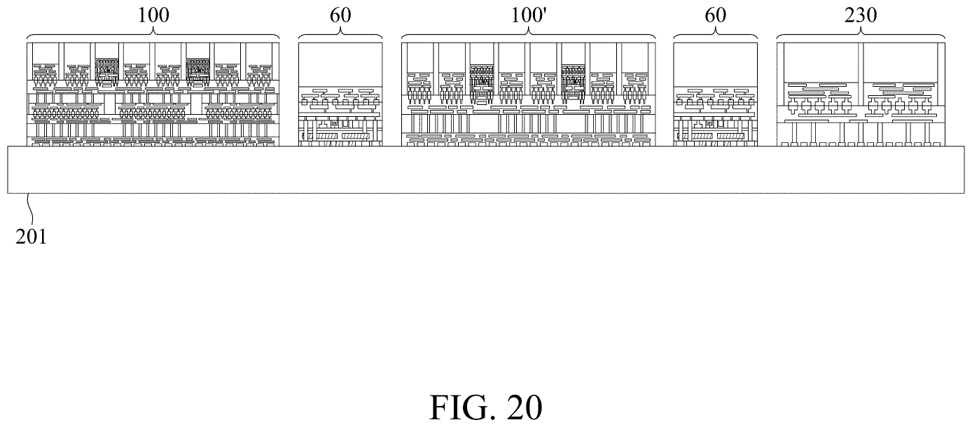

FIGS. 20 through 24 illustrate the formation of a package 200, in accordance with some embodiments. The package 200 comprises a plurality of optical bridge modules 60 attached to the interposer structure 220 that facilitate optical communication along the waveguides 216 of the interposer structure 220. The package 200 also comprises a plurality of modules attached to the interposer structure 220, which may be similar to the package modules 100 or 100′ described previously, or which may be another type of module (e.g., module 230, described below). In some embodiments, the package 200 is a chip-on-wafer (CoW) package or the like, although it should be appreciated that embodiments may be applied to other three-dimensional integrated circuit (3DIC) packages. In an embodiment, the package 200 may be a part of a larger package, such as a chip-on-wafer-on-substrate (CoWoS) package or the like, although it should be appreciated that embodiments may be applied to other 3DIC packages.

In FIG. 20, a plurality of package modules and a plurality of optical bridge modules 60 are attached to a first carrier 201, in accordance with some embodiments. The optical bridge modules 60 may be similar to those described previously for FIGS. 1-7. The package modules may be similar to other package modules described herein, such as the package module 100 of FIG. 14, the package module 100 of FIG. 15, the package module 100′ of FIG. 16, a combination thereof, or the like. A plurality of other modules 230 may also be attached to the first carrier 201, a representative example of which is shown in FIG. 20 by module 230. The modules 230 may include one or more types of components, chips, dies, SoIC devices, or the like. For example, the modules 230 may be or may comprise components similar to those described previously for the first components 110 and/or the second components 130. Other types of modules 230 are possible, and more than one type of module 230 may be present. The first carrier 201 may be similar to the first carrier 101 described previously. In some cases, the package modules, the optical bridge modules 60, and the modules 230 may be attached to the first carrier 201 using an adhesive, a die attach film (DAF), or the like. Any suitable number of package modules, optical bridge modules 60, or modules 230 may be attached to the first carrier 201 in other embodiments.

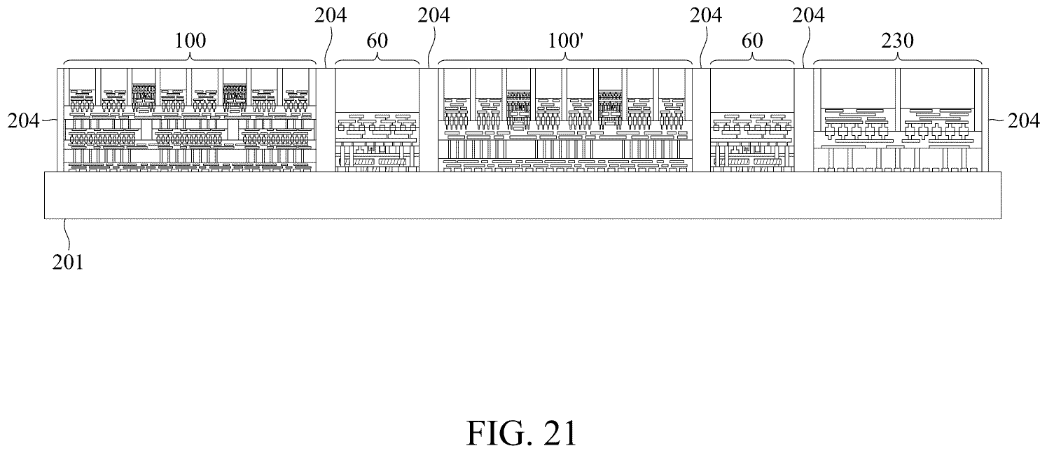

In FIG. 21, an encapsulant 204 is formed on and around the package modules (e.g., package modules 100/100′), the optical bridge modules 60, and the modules 230, in accordance with some embodiments. After formation, the encapsulant 204 encapsulates the package modules, the optical bridge modules 60, and the modules 230. The encapsulant 204 may be similar to the encapsulant 102 described previously. The encapsulant 204 may be formed over the first carrier 201 such that the package modules, the optical bridge modules 60, and/or the modules 230 are buried or covered. The encapsulant 204 may be applied in liquid or semi-liquid form and then subsequently cured. In some embodiments, a planarization process is performed on the encapsulant 204 to expose the package modules, the optical bridge modules 60, and/or the modules 230. Top surfaces of the package modules, the optical bridge modules 60, and/or the modules 230 may be substantially level or coplanar (within process variations) after performing the planarization process. The planarization process may comprise, for example, a CMP process, a grinding process, an etching process, or the like. In some embodiments, the planarization may be omitted.

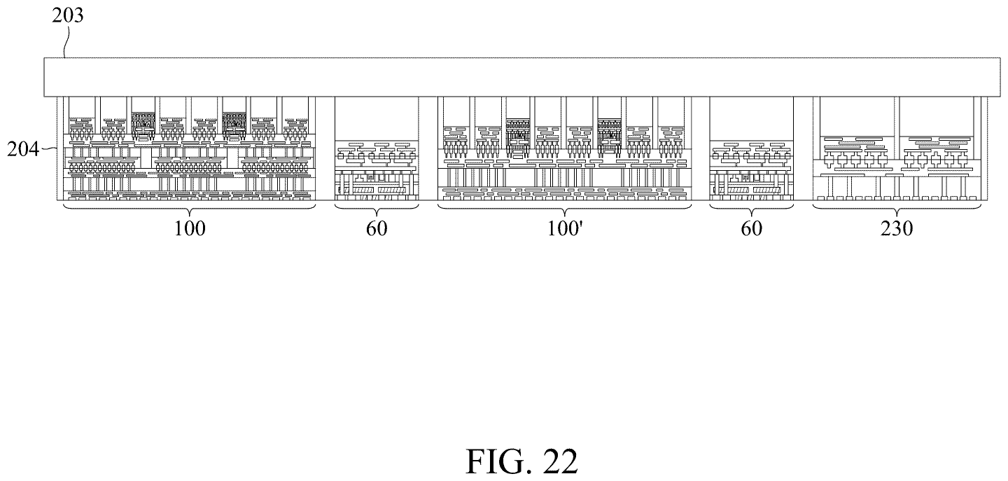

In FIG. 22, a second carrier 203 is attached to the structure and the first carrier 201 is removed, in accordance with some embodiments. The second carrier 203 is attached to the front side of the structure, and thus may be attached to the package modules, the optical bridge modules 60, the modules 230, and/or the encapsulant 204 in some cases. The second carrier 203 may be similar to the first carrier 201, and may be attached using an adhesive or other suitable technique. After attachment of the second carrier 203, the first carrier 201 is removed from the back side of the structure. Removing the first carrier 201 may expose the back sides of the package modules, the optical bridge modules 60, the modules 230, and/or the encapsulant 204, as shown in FIG. 22.

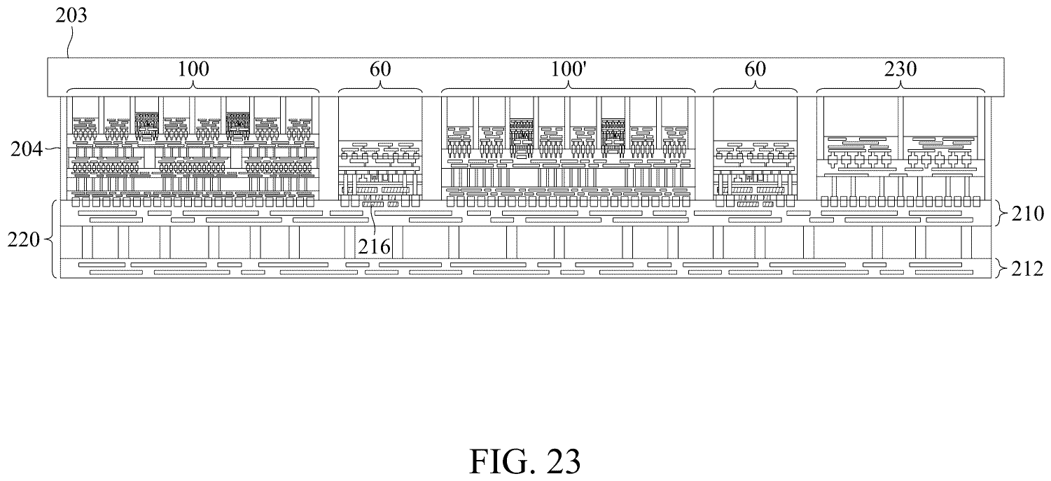

In FIG. 23, an interposer structure 220 is attached to the back side of the structure, in accordance with some embodiments. The interposer structure 220 may be similar to the interposer structure 220 described previously for FIGS. 17-19. The interposer structure 220 may be attached using dielectric-to-dielectric bonding and metal-to-metal bonding, in some embodiments. For example, conductive pads 214 of the interposer structure 220 may be bonded to corresponding bonding pads 145 of the package modules 100/100′, corresponding bonding pads 52 of the optical bridge modules 60, and corresponding bonding pads of the modules 230 (not separately labeled) using metal-to-metal bonding. In this manner, the interposer structure 220 is physically and electrically connected to the package modules 100/100′ the optical bridge modules 60, and/or the modules 230. The interposer structure 220 may also be bonded to the package modules 100/100′ the optical bridge modules 60, and/or the modules 230 using dielectric-to-dielectric bonding, in some embodiments.

After bonding the optical bridge modules 60 to the interposer structure 220, waveguides 48 of the optical bridge modules 60 may be optically coupled to waveguides 216 of the interposer structure 220. In this manner, optical signals may be transmitted between the optical bridge modules 60 and the interposer structure 220. For example, an optical bridge module 60 may receive optical signals from a waveguide 216 or may transmit optical signals into a waveguide 216. The waveguides 216 of the interposer structure 220 may extend from one optical bridge module 60 to another optical bridge module 60. The waveguides 216 allow optical communication between package modules 100/100′ and modules 230, in which the optical bridge modules 60 provide interfacing and processing of electrical signals and optical signals for the package modules 100/100′ and modules 230.

In FIG. 24, conductive connectors 206 are formed on the back side of the interposer structure 220 to form the package 200, in accordance with some embodiments. Prior to forming the conductive connectors 206, the second carrier 203 may be removed. The conductive connectors 206 are physically and electrically connected to conductive features of the interposer structure 220, and may be used to connect the package 200 to an external component or package substrate. The conductive connectors 206 may comprise, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 206 may include a conductive material such as solder, copper, aluminum, gold, nickel, silver, palladium, tin, the like, or a combination thereof. In some embodiments, the conductive connectors 206 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 206 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In some embodiments, the conductive connectors 206 comprise under-bump metallizations (UBMs). In other embodiments, the conductive connectors 206 are bonding pads used for metal-to-metal bonding to an external component.

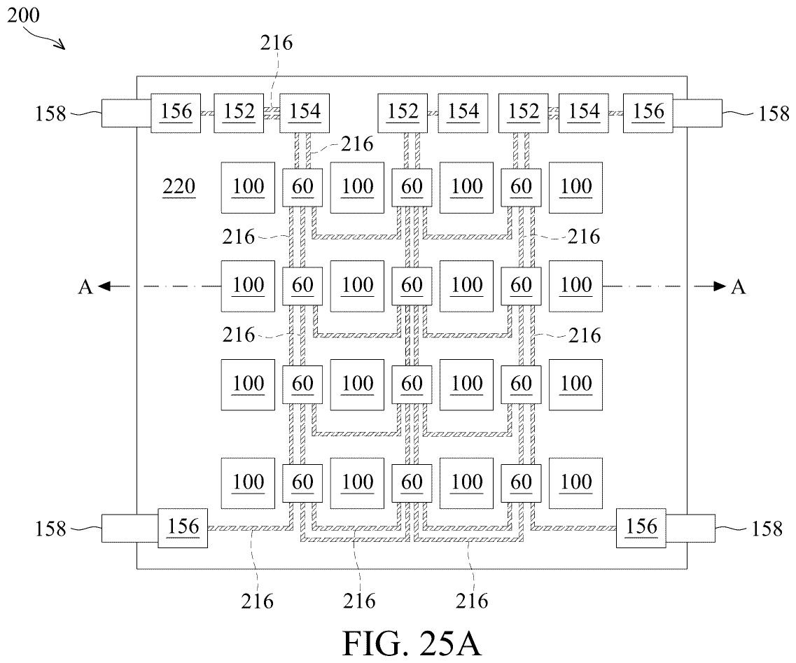

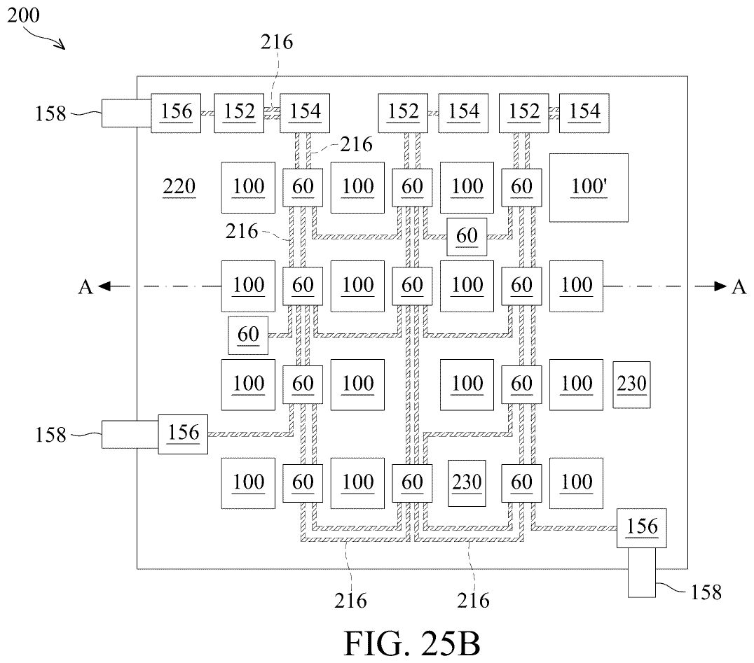

FIGS. 25A and 25B illustrates a schematic plan views of packages 200, in accordance with some embodiments. The packages 200 may be similar to the package 200 described for FIG. 24. For example, the packages 200 of FIGS. 25A-25B may include an interposer structure 220 comprising waveguides 216, a plurality of optical bridge modules 60, a plurality of package modules 100/100′, and/or a plurality of modules 230. The interposer structure 220, the package modules 100/100′, the modules 230, and the optical bridge modules 60 may be similar to those described for FIG. 24. The cross-sectional view of FIG. 24 may correspond to a cross-section similar to the representative cross-sections A-A shown in FIG. 25A and FIG. 25B. The package 200 shown in FIG. 25A has only package modules 100 and optical bridge modules 60, and the package 200 shown in FIG. 25B also includes a package module 100′ and a module 230.

In some embodiments, a package 200 also includes optical devices 152, optical engines 154, and/or fiber array units (FAU) 156 that are optically coupled to the waveguides 216. The optical devices 152 and optical engines 154 may be attached to the interposer structure 220 or may be within the interposer structure 220. The optical devices 152 may comprise, for example, laser diodes, III-V semiconductor devices, II-VI semiconductor devices, dies, chips, chiplets, or the like. In some embodiments, the optical devices 152 provide optical power to the waveguides 216. The optical engines 154 may comprise, for example, photonic devices (e.g., PIC structures), dies, chips, chiplets, or the like. Each optical engine 154 may control the operation of an optical device 152 and/or modulate the output of an optical device 152, in some embodiments. In this manner, the optical devices 152 may provide optical power into optical engines 154, and the optical engines 154 may control the optical power provided to the waveguides 126. In some embodiments, the FAUs 156 may be coupled to fiber structures 158, which may be optical fibers, fiber arrays, or the like. In this manner, a FAU 156 can facilitate transmission of optical signals from a fiber structure 158 into the waveguides 216 and/or facilitate transmission of optical signals from the waveguides 216 into a fiber structure 158.

Referring first to FIG. 25A, each optical bridge module 60 may be located adjacent to a package module 100 or between neighboring package modules 100. A package module 100 adjacent to an optical bridge module 60 may be associated with that optical bridge module 60 and may communicate electrically with that optical bridge module 60. As shown in FIG. 25A, each optical bridge module 60 is optically connected to one or more other optical bridge modules 60 by the waveguides 216 of the interposer structure 220. The waveguides 216 are utilized to transmit optical signals within the package 200, such as optical signals transmitted between optical bridge modules 60. In this manner, the waveguides 216 may be used to provide relatively long-distance package-level optical communication within the package 200 using optical signals. By communicating electrical signals over short distances through the conductive lines of the interposer structure 220 and communicating optical signals over long distances using the waveguides 216 of the interposer structure 220 and the optical bridge modules 60, the efficiency, speed, and/or bandwidth of a package 200 may be improved, and manufacturing cost may be reduced. In some embodiments, a package 200 includes optical bridge modules 60 that facilitate package-level optical communications and optical bridge components 160 within a module that facilitates module-level optical communications.

The number, arrangement, or configuration of the features, waveguides, or modules of a package 200 may have any suitable variations. As a non-limiting example, FIG. 25B illustrates a schematic plan view of a package 200, in accordance with some embodiments. The package 200 of FIG. 25B is similar to the package 200 of FIG. 25B, but has a different arrangement of some features. While FIG. 25A illustrates a package 200 in which the optical bridge modules 60 are arranged in rows between neighboring package modules 100, the optical bridge modules 60 may be arranged in any suitable configuration. As an illustrative example, the package 200 of FIG. 25B shows optical bridge modules 60 arranged on various sides of some package modules 100. In other words, the optical bridge modules 60 may be arranged in rows and/or in columns as desired. While the package 200 of FIG. 25A only includes package modules 100, the package 200 of FIG. 25B shows that package modules 100′ or modules 230 (or other types of modules not shown) may be used instead of package modules 100 or in addition to package modules 100. In other embodiments, a package 200 may include only package modules 100′, modules 230, other types of modules, or a combination thereof. Additionally, the waveguides 216 of the interposer structure 220 may have any number, configuration, or arrangement that provides suitable optical interconnection for a package 200.

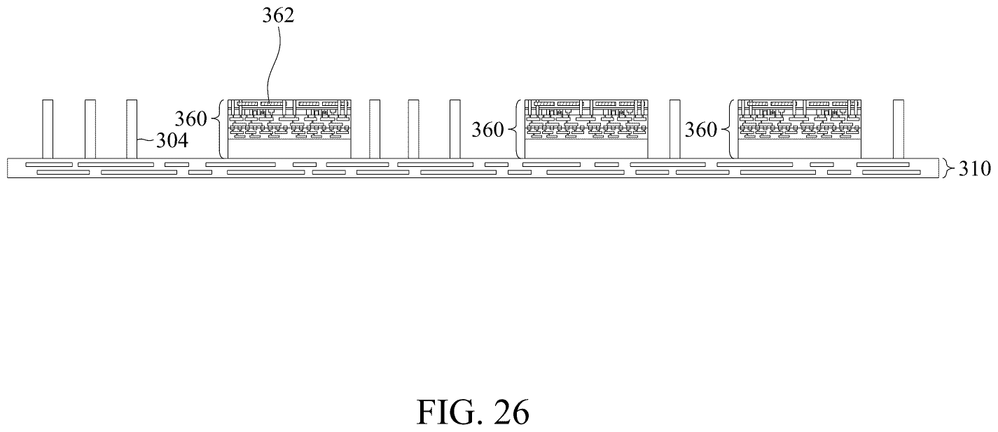

FIGS. 26 through 29 illustrate intermediate steps in the formation of a package 300, in accordance with some embodiments. The package 300 is similar to the package(s) 200 described previously, except that the optical bridge modules are formed within the interconnect structure. As an example of formation of the package 300, FIG. 26 illustrates through vias 304 and optical bridge modules 360 formed on a back side redistribution structure 310, in accordance with some embodiments. The back side redistribution structure 310 may be similar to the back side interconnect structure 211 (see FIG. 19), the redistribution structure 120 (see FIG. 14), or the back side interconnect structure 144 (see FIG. 14). The back side redistribution structure 310 may be formed using materials or techniques similar to these. For example, the back side redistribution structure 310 may comprise one or more layers of conductive features formed in one or more layers of dielectric layers.

The optical bridge modules 360 may be similar to the optical bridge modules 60 described previously. For example, the optical bridge modules 360 may comprise an EIC structure bonded to a PIC structure (not individually labeled), in which the PIC structure comprises waveguides 362. In some embodiments, the optical bridge modules 360 are attached to the back side redistribution structure 310 using an adhesive or the like. In some cases, the optical bridge modules 360 are attached such that the waveguides 362 are opposite from the back side redistribution structure 310. For example, the EIC structures of the optical bridge modules 360 may be attached to the back side redistribution structure 310.

As an example to form the through vias 304, a seed layer (not shown) is formed over the back side redistribution structure 310. In some embodiments, the seed layer is a metal layer, which may be a single layer or a composite layer comprising a plurality of sub-layers formed of different materials. In a particular embodiment, the seed layer comprises a titanium layer and a copper layer over the titanium layer. The seed layer may be formed using, for example, PVD or the like. A photoresist is formed and patterned on the seed layer. The photoresist may be formed by spin coating or the like and may be exposed to light for patterning. The pattern of the photoresist corresponds to conductive vias. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the through vias 304. The through vias 304 may be formed before or after attachment of the optical bridge modules 360.

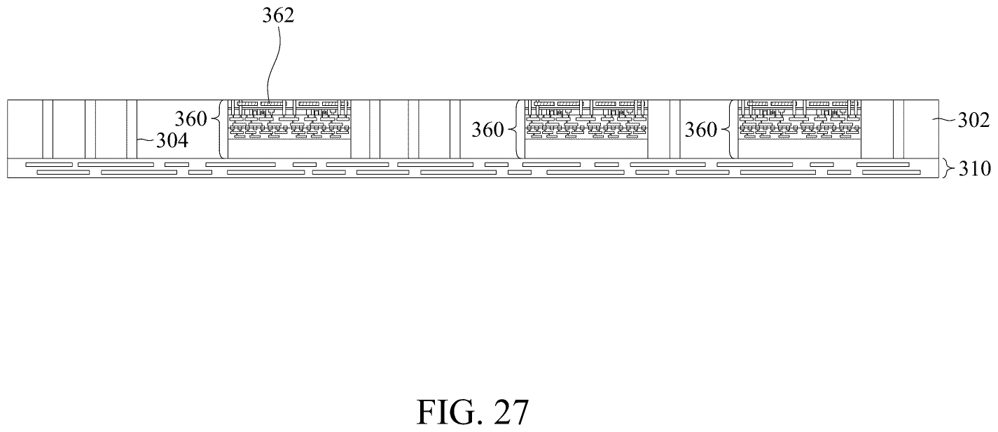

In FIG. 27, an encapsulant 302 is formed on and around the through vias 304 and the optical bridge modules 360, in accordance with some embodiments. After formation, the encapsulant 302 encapsulates the through vias 304 and the optical bridge modules 360. The encapsulant 302 may be similar to the encapsulant 102 or 204 described previously for the package 200. The encapsulant 302 may be formed over the back side redistribution structure 310 such that the through vias 304 and/or the optical bridge modules 360 are buried or covered. The encapsulant 302 may be applied in liquid or semi-liquid form and then subsequently cured.

In some embodiments, a planarization process is performed on the encapsulant 302 to expose the through vias 304 and the optical bridge modules 360. Top surfaces of the through vias 304 and the optical bridge modules 360, and/or the encapsulant 302 may be substantially level or coplanar (within process variations) after performing the planarization process. The planarization process may comprise, for example, a CMP process, a grinding process, an etching process, or the like. In some embodiments, the planarization may be omitted.

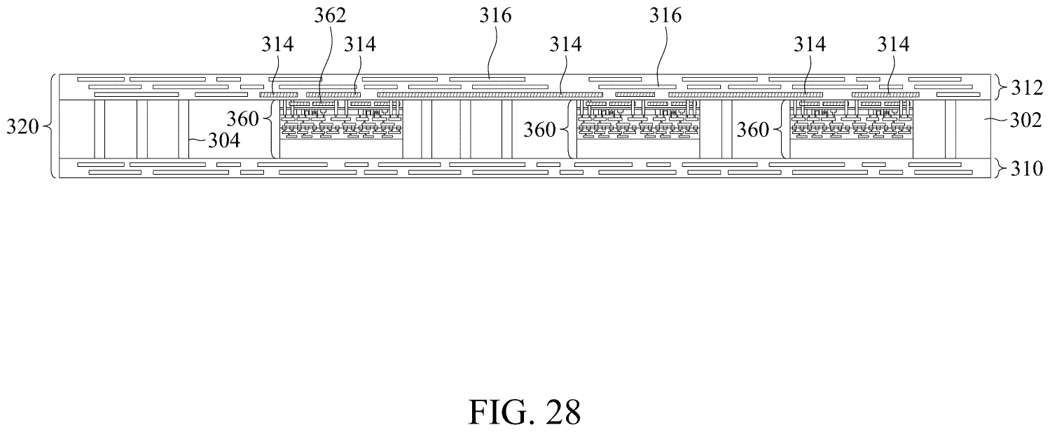

In FIG. 28, a front side redistribution structure 312 is formed over the through vias 304, the optical bridge modules 360, and the encapsulant 302, in accordance with some embodiments. The front side redistribution structure 312 may be similar to the redistribution structure 120 or the front side interconnect structure 210 (see FIG. 18) described previously. The front side redistribution structure 312 may be formed using materials or techniques similar to these. For example, the front side redistribution structure 312 comprises one or more layers of conductive features 316 and one or more layers of waveguides 314 formed in one or more dielectric layers (not individually illustrated), in some embodiments. The waveguides 314 may be formed over the waveguides 362 of optical bridge modules 360, and may be optically coupled to waveguides 362 of optical bridge modules 360. In this manner, the waveguides 314 and the optical bridge modules 360 may facilitate optical communication within the package 300. In this manner, an interposer structure 320 may be formed in which optical bridge modules 360 are sandwiched between redistribution structures 310/312. Forming optical bridge modules 360 within the interposer structure 320 can reduce the dimensions of a package 300 and increase device density of a package 300, in some cases.

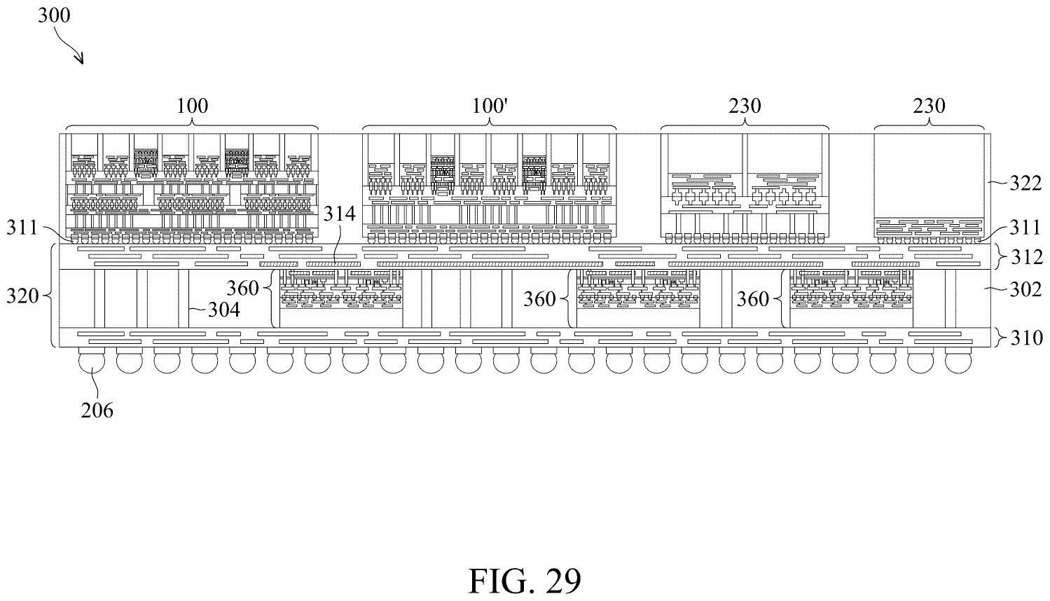

In FIG. 29, package modules 100/100′ and modules 230 are attached to the front side interconnect structure 312, in accordance with some embodiments. In some embodiments, the package modules 100/100′ and modules 230 are attached to the front side interconnect structure 312 using conductive connectors 311, which may be similar to the conductive connectors 206 described previously for FIG. 24. In some embodiments, an underfill (not illustrated) may be formed around the conductive connectors 311. In other embodiments, the package modules 100/100′ and modules 230 are attached to the front side interconnect structure 312 using metal-to-metal bonding. As shown in FIG. 29, in some embodiments, the package modules 100/100′ and/or modules 230 overlap underlying optical bridge modules 360.

After attaching the package modules 100/100′ and modules 230, an encapsulant 322 may be formed, in some embodiments. The encapsulant 322 encapsulates the package modules 100/100′ and modules 230. The encapsulant 302 may be similar to the encapsulants 322, 102, or 204 described previously. In some embodiments, a planarization process is performed on the encapsulant 322 to expose the package modules 100/100′ and modules 230. Top surfaces of the package modules 100/100′, the modules 230, and/or the encapsulant 322 may be substantially level or coplanar (within process variations) after performing the planarization process. The planarization process may comprise, for example, a CMP process, a grinding process, an etching process, or the like. In some embodiments, the planarization may be omitted. Conductive connectors 206 may be formed on the back side redistribution structure 310.

This is an example, and a package similar to package 300 may be formed using other process steps. As another example, the through vias 304 may be formed on a carrier, and the optical bridge modules 360 may be attached to the carrier. The front side redistribution structure 312 may then be formed, and the package modules 100/100′ and modules 230 attached to the front side redistribution structure 312. The back side redistribution structure 310 may then be formed to form the package 300. Other process steps are possible, and the process steps may be formed in another order than these examples.

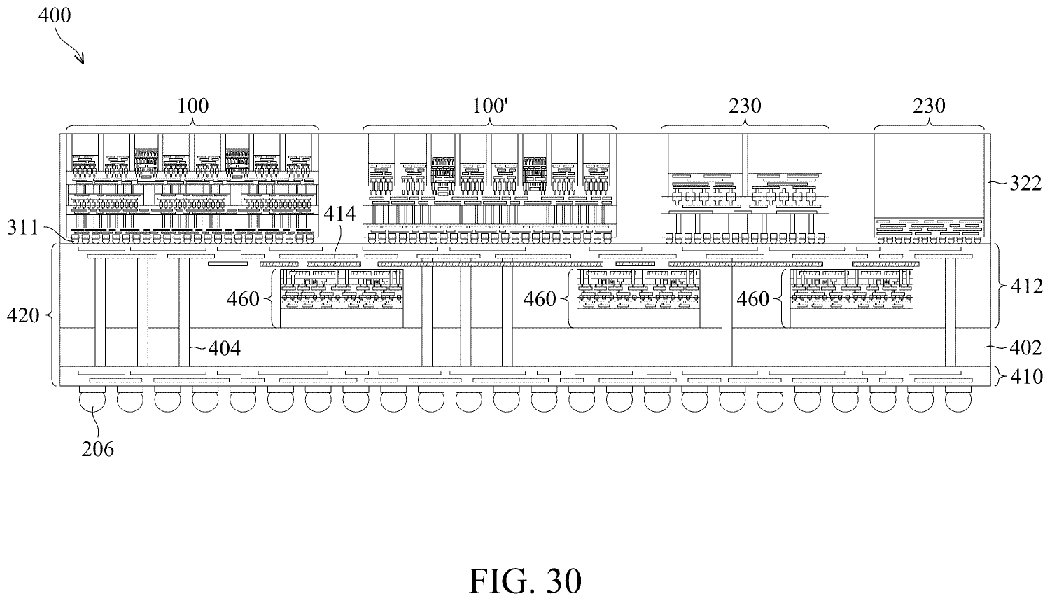

FIG. 30 illustrates a package 400, in accordance with some embodiments. The package 400 is similar to the package 300, except that the package 400 includes an interposer structure 420 comprising an interposer substrate 402. In some embodiments, optical bridge modules 460 are attached to the interposer substrate 402. The optical bridge modules 460 may be similar to the optical bridge modules 360 of the package 300. The interposer substrate 402 may be a glass substrate, an oxide substrate, or the like. The optical bridge modules 460 may be attached to the interposer substrate 402 using an adhesive or using dielectric-to-dielectric bonding, in some embodiments. A back side redistribution structure 410 may be formed on the back side of the interposer substrate 402, which may be similar to the back side redistribution structure 310 of the package 300.

A front side redistribution structure 412 may be formed over the interposer substrate 402 and the optical bridge modules 460, which may be similar to the front side redistribution structure 312 of the package 300, except that the front side redistribution structure 412 is formed on the interposer substrate 402 and may surround the optical bridge modules 460. For example, the front side redistribution structure 412 may comprise conductive features and waveguides 414 formed in a plurality of dielectric layers. The waveguides 414 are optically coupled to the optical bridge modules 460 and provide optical communication within the package 400. Through vias 404 may be formed through the interposer substrate 402 that electrically couple the front side redistribution structure 412 and the back side redistribution structure 410. The through vias 404 may extend into the front side redistribution structure 412, as shown in FIG. 30. Package modules 100/100′ and/or modules 230 may be attached to the front side interconnect structure 412 and encapsulated by an encapsulant 322. As shown in FIG. 30, in some embodiments, the package modules 100/100′ and/or modules 230 overlap underlying optical bridge modules 460. This is an example, and other configurations or process steps are possible.

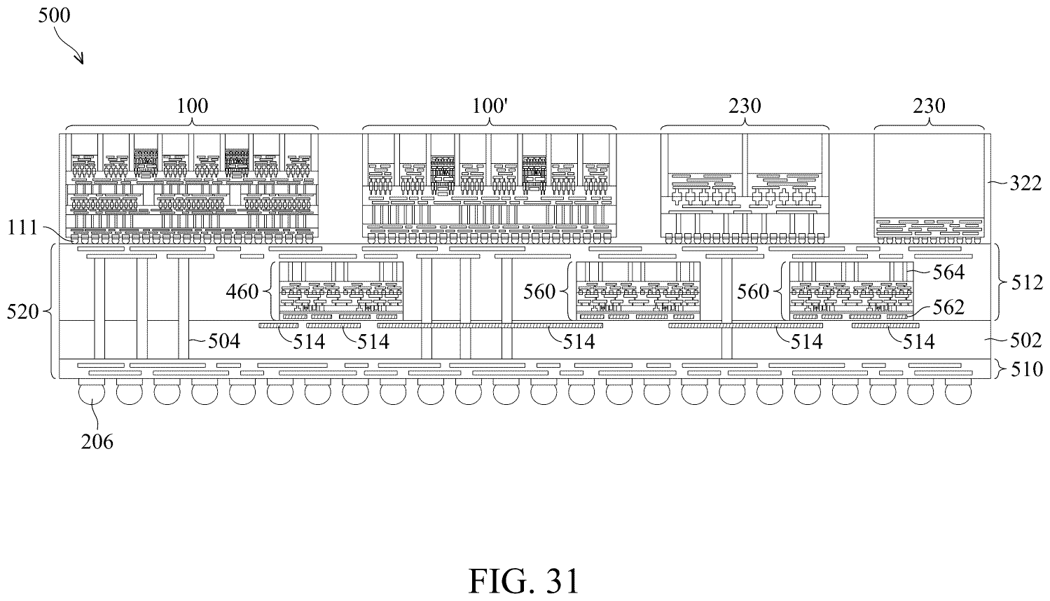

FIG. 31 illustrates a package 500, in accordance with some embodiments. The package 500 is similar to the package 400, except that waveguides 514 are formed in the interposer substrate 502 of the interposer structure 520 rather than in the front side interconnect structure 512 of the interposer structure 520. Accordingly, the PIC structures of the optical bridge modules 560 are attached to the interposer substrate 502 such that waveguides 562 of the optical bridge modules 560 are adjacent the waveguides 514 of the interposer substrate 502. In this manner, the waveguides of the optical bridge modules 560 may be optically coupled to the waveguides 514 of the interposer substrate 502. The optical bridge modules 560 may be similar to the optical bridge modules 360 of the package 300, except that through vias 564 extend through the EIC structure to make electrical connections with the front side interconnect structure 512.

The interposer substrate 502 may be a glass substrate, an oxide substrate, or the like. In some embodiments, the waveguides 514 may be formed in the interposer substrate 502 using a laser-writing process or the like. The optical bridge modules 560 may be attached to the interposer substrate 502 using dielectric-to-dielectric bonding, in some embodiments. The waveguides 514 are optically coupled to the optical bridge modules 560 and provide optical communication within the package 500. A back side redistribution structure 510 may be formed on the back side of the interposer substrate 502, which may be similar to the back side redistribution structure 310 of the package 300.

The front side redistribution structure 512 may be formed over the interposer substrate 502 and the optical bridge modules 560. The front side redistribution structure 512 which may be similar to the front side redistribution structure 412 of the package 400, except that the front side redistribution structure 512 is electrically connected to through vias 564 of the optical bridge modules 560. For example, the front side redistribution structure 512 may comprise conductive features formed in a plurality of dielectric layers.

Through vias 504 may be formed through the interposer substrate 502 that electrically couple the front side redistribution structure 512 and the back side redistribution structure 510. The through vias 504 may extend into the front side redistribution structure 512, as shown in FIG. 31. Package modules 100/100′ and/or modules 230 may be attached to the front side interconnect structure 512 and encapsulated by an encapsulant 322. As shown in FIG. 31, in some embodiments, the package modules 100/100′ and/or modules 230 overlap underlying optical bridge modules 560. This is an example, and other configurations or process steps are possible.

Embodiments of the present disclosure have some advantageous features. The use of an optical bridge modules as described herein can enable optical communication at a package level. The use of optical bridge modules can reduce manufacturing cost, reduce package size, and enable optical communication between various modules, dies, or devices of a package. By using electrical signals over short distances and optical signals over long distances as described herein, the efficiency, speed, throughput and/or bandwidth of a package may be improved. Additionally, using optical communication can generate less heat than electrical communication, thus the embodiments described herein can reduce the heat generated by a package. The embodiments described herein can facilitate both electrical communication and optical communication within a package, which can improve data communication speed with in a package. The techniques described herein can also allow for various optical bridge structures that enable module-level optical communication and package-level optical communication within the same package.

In an embodiment of the present disclosure, a package includes a first interconnect structure that includes conductive features and first waveguides; package modules attached to the first interconnect structure; and optical bridge modules attached to the first interconnect structure, wherein the optical bridge modules are optically coupled to the first waveguides, wherein the optical bridge modules are electrically connected to the corresponding package modules through the first interconnect structure. In an embodiment, the package modules and the optical bridge modules are attached to opposite sides of the first interconnect structure. In an embodiment, the first interconnect structure is an interposer. In an embodiment, the first interconnect structure laterally surrounds respective optical bridge modules. In an embodiment, at least one first waveguide is optically coupled to two or more optical bridge modules. In an embodiment, the optical bridge modules are sandwiched between the first interconnect structure and a second interconnect structure. In an embodiment, each optical bridge module respectively includes photonic components and second waveguides, wherein the respective second waveguides are optically coupled to the respective photonic components. In an embodiment, an encapsulant laterally separates package modules from adjacent optical bridge modules.

In an embodiment of the present disclosure, a package includes an interposer that includes a first waveguide; a first package module attached to a front side of the interposer; and a first optical package module that includes a second waveguide, wherein the second waveguide is optically coupled to the first waveguide; and a second optical package module that includes a third waveguide, wherein the third waveguide is optically coupled to the first waveguide. In an embodiment, the first optical package module and the second optical package module are attached to the front side of the interposer. In an embodiment, the first optical package module and the second optical package module are within the interposer. In an embodiment, the first waveguide is between the first optical package module and the first package module. In an embodiment, the package includes an encapsulant laterally surrounding the first optical package module and the second optical package module. In an embodiment, the interposer includes a glass substrate, wherein the first optical package module and the second optical package module are attached to the glass substrate. In an embodiment, the first waveguide is within the glass substrate. In an embodiment, top surfaces of the first package module, the first optical package module, and the second optical package module are level.

In an embodiment of the present disclosure, a method includes forming an optical bridge structure, including: forming first waveguides; forming photonic components over the first waveguides; forming an interconnect structure over the photonic components; and bonding a first semiconductor die to the interconnect structure; forming an interposer structure, wherein forming the interposer structure includes forming second waveguides and conductive features within insulating layers; bonding the optical bridge structure to the interposer structure using metal-to-metal bonding, wherein the first waveguides are optically coupled to the second waveguides after bonding; and bonding a second semiconductor die to the interposer structure using metal-to-metal bonding. In an embodiment, the second semiconductor die includes an optical bridge component attached to a redistribution structure and optically coupled to third waveguides within the redistribution structure. In an embodiment, the second semiconductor die is free of waveguides. In an embodiment, the first semiconductor die is bonded to the interconnect structure using metal-to-metal bonding.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package comprising:
a first interconnect structure comprising a plurality of conductive features and a plurality of first waveguides;
a plurality of package modules attached to the first interconnect structure; and
a plurality of optical bridge modules attached to the first interconnect structure, wherein the optical bridge modules are optically coupled to the plurality of first waveguides, wherein the optical bridge modules are electrically connected to the corresponding package modules through the first interconnect structure.

2. The package of claim 1, wherein the plurality of package modules and the plurality of optical bridge modules are attached to opposite sides of the first interconnect structure.

3. The package of claim 1, wherein the first interconnect structure is an interposer.

4. The package of claim 1, wherein the first interconnect structure laterally surrounds respective optical bridge modules of the plurality of optical bridge modules.

5. The package of claim 1, wherein at least one first waveguide of the plurality of first waveguides is optically coupled to two or more optical bridge modules of the plurality of optical bridge modules.

6. The package of claim 1, wherein the plurality of optical bridge modules is sandwiched between the first interconnect structure and a second interconnect structure.

7. The package of claim 1, wherein each optical bridge module respectively comprises a plurality of photonic components and a plurality of second waveguides, wherein the respective plurality of second waveguides is optically coupled to the respective plurality of photonic components.

8. The package of claim 1, wherein an encapsulant laterally separates package modules from adjacent optical bridge modules.

9. A package comprising:
an interposer comprising a first waveguide;
a first package module attached to a front side of the interposer; and
a first optical package module comprising a second waveguide, wherein the second waveguide is optically coupled to the first waveguide; and
a second optical package module comprising a third waveguide, wherein the third waveguide is optically coupled to the first waveguide.

10. The package of claim 9, wherein the first optical package module and the second optical package module are attached to the front side of the interposer.

11. The package of claim 9, wherein the first optical package module and the second optical package module are within the interposer.

12. The package of claim 11, wherein the first waveguide is between the first optical package module and the first package module.

13. The package of claim 9 further comprising an encapsulant laterally surrounding the first optical package module and the second optical package module.

14. The package of claim 9, wherein the interposer comprises a glass substrate, wherein the first optical package module and the second optical package module are attached to the glass substrate.

15. The package of claim 14, wherein the first waveguide is within the glass substrate.

16. The package of claim 9, wherein top surfaces of the first package module, the first optical package module, and the second optical package module are level.

17. A method comprising:
forming an optical bridge structure, comprising:
forming a plurality of first waveguides;
forming a plurality of photonic components over the plurality of first waveguides;
forming an interconnect structure over the plurality of photonic components; and
bonding a first semiconductor die to the interconnect structure;
forming an interposer structure, wherein forming the interposer structure comprises forming a plurality of second waveguides and a plurality of conductive features within a plurality of insulating layers;
bonding the optical bridge structure to the interposer structure using metal-to-metal bonding, wherein the plurality of first waveguides are optically coupled to the plurality of second waveguides after bonding; and
bonding a second semiconductor die to the interposer structure using metal-to-metal bonding.

18. The method of claim 17, wherein the second semiconductor die comprises an optical bridge component attached to a redistribution structure and optically coupled to a plurality of third waveguides within the redistribution structure.

19. The method of claim 17, wherein the second semiconductor die is free of waveguides.

20. The method of claim 17, wherein the first semiconductor die is bonded to the interconnect structure using metal-to-metal bonding.
